(19) United States
(12) Patent Application Publication
(10) Pub. No.: US 2025/0114996 A1
(43) Pub. Date: Apr. 10, 2025

(54) PIEZOELECTRIC COMPOSITES COMPRISING PIEZOELECTRIC PARTICLES COMPATIBILIZED WITH A POLYMER MATERIAL AND USE THEREOF IN ADDITIVE MANUFACTURING

(71) Applicants: XEROX CORPORATION, Norwalk, CT (US); NATIONAL RESEARCH COUNCIL OF CANADA, Ottawa (CA)

(72) Inventors: Sarah J. VELLA, Milton (CA); Alexandros VASILEIOU, Toronto (CA); Yujie ZHU, Mississauga (CA); Edward G. ZWARTZ, Mississauga (CA); Chantal PAQUET, Ottawa (CA); Silvio E. KRUGER, Brossard (CA); Yujie ZHANG, Ottawa (CA); Derek ARANGUREN VAN EGMOND, Mississauga (CA); Thomas LACELLE, Kanata (CA); Mohammad RAFIEE, Stittsville (CA); Claudie ROY, Montreal (CA)

(73) Assignees: XEROX CORPORATION, Norwalk, CT (US); NATIONAL RESEARCH COUNCIL OF CANADA, Ottawa, ON (CA)

(21) Appl. No.: 18/052,069

(22) PCT Filed: Mar. 22, 2022
(86) PCT No.: PCT/US2022/021353

§ 371 Date: Nov. 2, 2022

Related U.S. Application Data
(60) Provisional application No. 63/164,679, filed on Mar. 23, 2021.

(51) Int. Cl. B29C 64/118; B29K 23/00; B29K 105/00; B29K 105/16; B29K 505/08; B33Y 10/00; B33Y 70/10; C08K 9/04; C08L 53/00

(52) U.S. Cl. CPC B29C 64/118; B33Y 10/00; B33Y 70/10; C08K 9/04; C08L 53/005; B29K 2023/18; B29K 2105/0085; B29K 2105/0088; B29K 2105/16; B29K 2505/08; C08K 2201/005; C08L 2205/025

(57) ABSTRACT

Parts made by additive manufacturing are often structural in nature, rather than having functional properties conveyed by a polymer or other component present therein. Printed parts having piezoelectric properties may be formed using compositions comprising a polymer material comprising at least one thermoplastic polymer, at least one polymer precursor, or any combination thereof, and a plurality of piezoelectric particles dispersed in at least a portion of the polymer material. The piezoelectric particles may interact non-covalently with at least a portion of the polymer material, be covalently bonded to at least a portion of the polymer material, and/or be reactive with at least a portion of the polymer material. The compositions may be extrudable and formable into a self-standing three-dimensional structure upon being extruded. Additive manufacturing processes may comprise forming a printed part by depositing the compositions layer-by-layer.

### FIELD

The present disclosure generally relates to additive manufacturing and, more particularly, extrudable compositions suitable for additive manufacturing to form printed parts exhibiting piezoelectric properties.

### BACKGROUND

Additive manufacturing, also known as three-dimensional (3-D) printing, is a rapidly growing technology area. Although additive manufacturing has traditionally been used for rapid prototyping activities, this technique is being increasingly employed for producing commercial and industrial parts in any number of complex shapes. Additive manufacturing processes typically operate by building an object (part) layer-by-layer, for example, by 1) depositing a stream of molten printing material obtained from a continuous filament or other printing material source, 2) sintering powder particulates of a printing material using a laser, or 3) direct writing using an extrudable paste composition. The layer-by-layer deposition usually takes place under control of a computer to deposit the printing material in precise locations based upon a digital three-dimensional “blueprint” of the part to be manufactured, with consolidation of the printing material often taking place in conjunction with deposition to form the printed part. The printing material forming the body of a printed part may be referred to as a “build material” herein.

Additive manufacturing processes employing a stream of molten printing material for part formation may utilize a thermoplastic polymer filament as a source of the molten printing material. Such additive manufacturing processes are sometimes referred to as “fused deposition modeling” or “fused filament fabrication” processes. The latter term is used herein. Additive manufacturing processes employing thermoplastic polymer pellets or other polymer forms as a source of printing material are also known. Extrudable paste compositions comprising thermoplastic polymers or curable polymer precursors (resins) may also be utilized in similar direct writing additive manufacturing processes.

Additive manufacturing processes employing powder particulates of a printing material oftentimes perform directed heating in selected locations of a particulate bed (powder bed) following printing material deposition to promote coalescence of the powder particulates into a consolidated part. Techniques suitable for promoting consolidation of powder particulates to form a consolidated part include, for example, Powder Bed Fusion (PBF), selective laser sintering (SLS), Electron Beam Melting (EBM), Binder Jetting and Multi-Jet Fusion (MJF).

A wide range of parts having various shapes may be fabricated using the foregoing additive manufacturing processes. In many instances, build materials employed in such additive manufacturing processes may be largely structural in nature, rather than the polymer having an innate functionality itself. One exception is piezoelectric functionality, which may be exhibited in printed objects formed from polyvinylidene fluoride, a polymer which possesses innate piezoelectric properties upon poling. Piezoelectric materials generate charge under mechanical strain or, conversely, undergo mechanical strain when a potential is applied thereto. Potential applications for piezoelectric materials include, for example, sensing, switching, actuation, and energy harvesting.

Despite the desirability of forming printed parts having piezoelectric properties, there are only limited options for doing so at present. Other than polyvinylidene fluoride, the range of piezoelectric polymers is rather limited, and some alternative polymers are not suitable for being printed in additive manufacturing processes employing extrusion. For example, crosslinked polymers are completely unworkable once they have been crosslinked, and polymer resins suitable for forming crosslinked polymers may not by themselves afford form factors suitable for printing in fused filament fabrication and similar printing processes and/or printed parts formed from polymer resins may not be self-supporting before crosslinking takes place. Moreover, the piezoelectricity of polyvinylidene fluoride is rather low compared to other types of piezoelectric materials. These shortcomings may limit the range of printed parts having a piezoelectric response that may be obtained through present additive manufacturing processes.

Numerous ceramic materials having high piezoelectricity are available, such as lead-zirconium-titanate (PZT), but they are not printable by themselves and are often very brittle. Moreover, high sintering temperatures (>300° C.) may be needed to promote part consolidation and piezoelectric particle interconnectivity after depositing predominantly a piezoelectric ceramic. Admixtures of polymers and piezoelectric particles have not yet afforded high piezoelectric performance in printed parts. Poor dispersion of the piezoelectric particles in the polymer, particle agglomeration, and limited interactions between the piezoelectric particles and the polymer are to blame in many instances. Without being bound by any theory, the limited interactions between the piezoelectric particles and the polymer results in poor load transfer to the piezoelectric particles, thereby lowering the piezoelectric response obtained therefrom when mechanical strain is applied. Particle agglomeration may also play a role in this regard.

### SUMMARY

In some embodiments, the present disclosure provides compositions comprising: a polymer material comprising at least one thermoplastic polymer, at least one polymer precursor, or any combination thereof; and a plurality of piezoelectric particles dispersed in at least a portion of the polymer material; wherein the piezoelectric particles: 1) interact non-covalently with at least a portion of the polymer material by π-π bonding, hydrogen bonding, electrostatic interactions stronger than van der Waals interactions, or any combination thereof; 2) are covalently bonded to at least a portion of the polymer material; 3) are reactive with at least a portion of the polymer material to form at least one covalent bond thereto under specified conditions; or 4) any combination thereof; wherein the composition is extrudable and formable into a self-standing three-dimensional structure upon being extruded. Printed parts may comprise the compositions.

In some or other embodiments, the present disclosure provides additive manufacturing processes comprising: providing a composition of the present disclosure; and forming a printed part by depositing the composition layer-by-layer.

### BRIEF DESCRIPTION OF THE DRAWINGS

The following figures are included to illustrate certain aspects of the present disclosure, and should not be viewed as exclusive embodiments. The subject matter disclosed is capable of considerable modifications, alterations, combinations, and equivalents in form and function, as will occur to one having ordinary skill in the art and having the benefit of this disclosure.

FIG. 1 shows a schematic of an illustrative fused filament fabrication process for producing a part using a build material and a removable support material.

FIG. 2 shows a schematic of an illustrative part having a first removable support interposed between the part and a print bed and a second removable support interposed between two portions of the part.

FIG. 3A is an illustrative overlay of FTIR spectra of PZT particles and PZT-Ph particles.

FIG. 3B is an illustrative overlay of FTIR spectra of PZT particles and PZT-NH₂ particles.

FIG. 3C is an illustrative overlay of FTIR spectra of PZT particles and PZT-Acr particles.

FIGS. 4A-1 and 4A-2 show illustrative SEM images for the samples of Example 2A and Comparative Example 2A, respectively.

FIGS. 5A-1 and 5A-2 show illustrative SEM images for the samples of Example 3A and Comparative Example 3A, respectively.

FIG. 6A is a diagram showing overlaid FTIR spectra of HDPE-g-MA (MFI=12 g/10 min) and the composite of Example 3B-2.

FIG. 6B is a diagram showing overlaid FTIR spectra of SEBS-g-MA and the composite of Example 6B.

FIG. 7 is a diagram showing overlaid FTIR spectra of HDPE-g-MA (MFI=12 g/10 mn) and the composite of Example 4B-2.

FIGS. 8A-8C show illustrative SEM images for HDPE composites produced in Examples 2B, 3B-1, and 4B-2, respectively.

FIGS. 9A and 9B show illustrative SEM images for SEBS composites produced in Examples 5B and 6B, respectively.

FIG. 10A shows an illustrative SEM image of a thermopressed disk containing the composite of Example 2C, in which the acrylate oligomer was uncured.

FIGS. 10B and 10C show illustrative SEM images of thermopressed disks containing the composite of Example 2C, in which the acrylate oligomer was cured on one or both sides of the disk, respectively.

FIG. 10D shows an illustrative SEM image of an uncured surface of a thermopressed disk containing the composite of Example 2C and showing porosity.

### DETAILED DESCRIPTION

The present disclosure generally relates to additive manufacturing and, more particularly, extrudable compositions suitable for additive manufacturing to form printed parts exhibiting piezoelectric properties. More specifically, the present disclosure provides compositions in which piezoelectric particles are combined with a polymer material in a composite having a form factor suitable for additive manufacturing, and in which piezoelectric particles have been compatibilized to increase interactions between the piezoelectric particles and the polymer material. The composites are extrudable and formable into a self-standing three-dimensional part upon being extruded, as explained further hereinbelow. Compatibilization of the piezoelectric particles and the polymer material may involve inducing non-covalent interactions, covalent bonding (including latent covalent bonding), or any combination thereof. Both pre-formed thermoplastic polymers, and/or polymer precursors may be present in the polymer material. The compatibilizing interactions between the piezoelectric particles and the polymer material may increase the piezoelectric response (piezoelectricity) obtained from the composites and printed parts formed therefrom. Suitable form factors for the composites may include, but not limited to, composite filaments, composite pellets, composite powders, and composite pastes.

As discussed above, additive manufacturing processes, such as fused filament fabrication, direct writing, or similar layer-by-layer deposition processes, are powerful tools for generating printed parts in a wide range of complex shapes. In many instances, the polymer materials used in layer-by-layer additive manufacturing processes are largely structural in nature and do not convey functional properties to a printed part by themselves. Polyvinylidene fluoride is a notable exception, which may form printed parts having piezoelectricity after suitable poling. Beyond polyvinylidene fluoride, there are few alternative polymer materials for introducing piezoelectricity to a printed part. Furthermore, the piezoelectricity of polyvinylidene fluoride may not be sufficiently large for some intended applications.

In response to the foregoing shortcomings, the present disclosure provides compositions that are composites capable of undergoing extrusion to form printed parts through layer-by-layer additive manufacturing. Extrusion of the composites may be aided by heating in some cases, such as heating the composites above a melting point or softening temperature of at least one thermoplastic polymer therein. The composites may comprise a polymer material and piezoelectric particles dispersed in at least a portion of the polymer material, wherein interactions between the piezoelectric particles and the polymer material have been compatibilized, specifically by introducing covalent bonding and/or non-covalent interactions between the piezoelectric particles and at least a portion of the polymer material. Thermoplastic polymers, optionally in further combination with at least one polymer precursor, may be present in the compositions, which remain extrudable even with the compatibiliizing interactions in place. The composites may have more robust mechanical properties than do piezoelectric particles alone, at the least being less brittle and more flexible, and may be formed more readily into printed parts than can the piezoelectric particles alone. Without being bound by any theory or mechanism, the compatibilizing interactions are believed to enhance the piezoelectric effect (piezoelectricity) by promoting load transfer from the polymer material to the piezoelectric particles, but without rendering the compositions into a non-extrudable form.

Advantageously, the compatiblizing interactions may aid in providing the compositions with the ability to form self-standing three-dimensional structures once extruded during an additive manufacturing process. The term “self-standing” means that a printed part holds its shape and/or exhibits a yield stress once the composition has been extruded into a desired shape. In contrast, compositions that do not hold their shape following extrusion are referred to as “conformal,” since they may assume the profile of the surface upon which they are deposited. In many instances, the ability for a composite to be extruded and the ability for the composite to provide a self-standing structure following extrusion are mutually exclusive features. For example, a composite that is extrudable may lack sufficient mechanical strength to support itself upon being deposited in a desired shape, and a composite that hold its shape within a three-dimensional structure may be too rigid to be extruded. The composites described herein may further be processed into various form factors capable of undergoing continuous extrusion. Thin films, monolithic layers, and similar quasi-2D structures are not considered to be self-standing shapes in the disclosure herein, since a substrate upon which these types of printed parts are formed may bear the load to retain the part's shape rather than the part itself being self-standing. It is to be appreciated, however, that the compositions described herein may be utilized to thin films and monolithic layers at the discretion of a user conducting a particular printing application.

More specifically, the compositions described herein comprise a plurality of piezoelectric particles that 1) interact non-covalently with at least a portion of a polymer material by π-π bonding, hydrogen bonding, electrostatic interactions stronger than van der Waals interactions, or any combination thereof, 2) are covalently bonded to at least a portion of the polymer material, 3) are reactive with at least a portion of the polymer material to form at least one covalent bond thereto under specified conditions (e.g., conditions encountered during or after printing), or 4) any combination thereof. Such compatibilizing interactions may occur with all or a portion of the polymer material. For example, the polymer material may comprise multiple thermoplastic polymers, of which only some of the thermoplastic polymers are compatibilized with the piezoelectric particles. In another example, a polymer precursor (e.g., a polymerizable monomer or oligomer and/or a curable resin) may be present in the polymer material in combination with at least one thermoplastic polymer, and the polymer precursor and/or the thermoplastic polymer may be compatibilized with the piezoelectric particles. Curable resins may become covalently crosslinked with themselves and optionally with the piezoelectric particles after printing, thereby not impacting the printing process. As still another option, covalent bonding in the compositions may be latent (including both covalent bonding that results in covalent crosslinking and covalent bonding that does not result in crosslinking), such that one or more covalent bonds may form during or after formation of a printed part according to the disclosure herein. Evidence of compatibilizing interactions between the polymer material and the piezoelectric particles may be demonstrated spectroscopically or by imaging showing improved dispersion of the piezoelectric particles within the polymer material and/or enhancement of the piezoelectric response in comparison to that produced in a composite without compatibilizing interactions being present.

To improve the piezoelectric response still further, carbon nanomaterials may optionally be included in the compositions disclosed herein. The carbon nanomaterials may increase stiffness of the polymer material in a composite and further facilitate load transfer from the polymer material to the piezoelectric particles, thereby increasing the piezoelectric response obtained therefrom. In addition, some carbon nanomaterials possess significant electrical conductivity and may increase the piezoelectric response attainable when present in combination with a given quantity of piezoelectric particles. At the very least, carbon nanomaterials that are electrically conductive may improve the efficiency of the poling process used to induce piezoelectricity in a printed part, thereby further enhancing the piezoelectric response attained therefrom. Like the piezoelectric particles, the carbon nanomaterials also optionally may be covalently bonded to at least a portion of the polymer material, including to a thermoplastic polymer or polymer precursor, and/or be covalently crosslinkable with themselves, the piezoelectric particles, and or a curable resin to facilitate the foregoing still further. Illustrative carbon nanomaterials that may be suitably used in the disclosure herein are specified further below. The carbon nanomaterials may likewise be dispersed in all or a portion of the polymer material.

Suitable form factors of the composites that may be processed by extrusion in the disclosure herein include composite filaments, composite pellets, composite powders, composite pastes, or any combination thereof. Additional details regarding these various form factors follows herein. Through choice of the components of the polymer material present therein, particularly at least one thermoplastic polymer, the compositions may remain extrudable once a composite with piezoelectric particles has been formed, thereby allowing printed parts to be formed directly through extrusion and solidification of the at least one thermoplastic polymer. Optionally, a polymer precursor, such as a curable resin, may be present in combination with at the at least one thermoplastic polymer in the polymer material. The term “curable resin” refers to a divalent polymerizable substance that undergoes covalent crosslinking upon being cured. After printing, the curable resin may form a stiff, crosslinked polymer matrix within or interpenetrating the at least one thermoplastic polymer in non-crosslinked form, optionally with crosslinking also occurring between the crosslinked polymer matrix and the piezoelectric particles. Such polymer precursors may be utilized for polymers that would otherwise be too stiff or not easily extruded when blended with piezoelectric particles in a composite. Advantageously, the combination of at least one thermoplastic polymer, optionally having piezoelectric particles covalently bonded thereto (or reactive therewith to form covalent bonds under specified conditions), and a polymer precursor, such as a curable resin, may remain readily extrudable and allow modification of a printed part to take place after printing. Namely, after forming a printed part by extrusion and layer-by-layer deposition of a suitable form factor, the polymer precursor may be converted to the corresponding covalently crosslinked polymer, either through polymerization or oligomerization of a polymerizable monomer or oligomer or through crosslinking of a curable resin. Curing may take place by photocuring and/or thermal curing of a reactive functional group in the curable resin to afford a covalently crosslinked polymer matrix. The stiffness of the resulting crosslinked polymer matrix may again promote load transfer to the piezoelectric particles to increase the piezoelectric response obtained therefrom. The piezoelectric particles need not necessarily be dispersed in the crosslinked polymer matrix for this benefit to be realized.

Advantageously, a range of thermoplastic polymers having functionality capable of forming covalent bonds with piezoelectric particles are commercially available or may be readily produced by modification of a parent polymer backbone. Moreover, covalent bonding may take place through surface functional groups natively present upon the piezoelectric particles, such as surface hydroxyl groups. Alternately, piezoelectric particles may be readily functionalized with a linker moiety containing a functional group capable of interacting non-covalently or undergoing a reaction to form a covalent bond with a complementary functional group upon the at least one thermoplastic polymer. In addition, covalent bond formation between the piezoelectric particles and the at least one thermoplastic polymer may occur latently. A range of covalent bonding types are suitable for use in the disclosure herein and may be envisioned by one having ordinary skill in the art. Example covalent bonding strategies are discussed in further detail below. In another example, the piezoelectric particles may contain a functional group (ligand) capable of coordinating a metal in piezoelectric particles by way of a coordinate covalent bond.

In addition, a range of polymer precursors capable of interacting non-covalently with piezoelectric particles, or forming covalent bonds or undergoing covalent crosslinking with piezoelectric particles are available. Similarly, piezoelectric particles may undergo covalent crosslinking through surface functional groups natively present upon the piezoelectric particles and/or the piezoelectric particles may be functionalized through a linker moiety containing a functional group capable of undergoing covalent crosslinking or covalent bonding.

Composite filaments and composite pellets containing a polymer material comprising at least one thermoplastic polymer having at least one compatibilizing interaction with piezoelectric particles may be obtained by melt blending. Polymer precursors and other optional components may be selected and included in amounts that do not significantly alter the melt blending process. Through selection of the polymer material and the amount of piezoelectric particles and other components present therein, these form factors may be formed into printed parts via extrusion and layer-by-layer deposition, such as through fused filament fabrication processes in the case of composite filaments, to afford significant piezoelectricity, after poling of the printed part. Composite filaments that are suitable for fused filament fabrication may have diameters that are appropriate for the drive unit for a particular printing system (common filament diameters include 1.75 mm and 2.85 mm). Other properties that may determine if a composite filament is suitable for fused filament fabrication include the temperature required to extrude the filament, which should not be undesirably high. A suitable composite filament for fused filament fabrication may further minimize printing issues, such as oozing from the print nozzle or clogging of the print nozzle, which may be impacted by the overall viscosity of the composite at the printing temperature. In addition, composite filaments suitable for fused filament fabrication may afford printed parts that easily separate from a print bed, have sufficient mechanical strength once printed, and exhibit good interlayer adhesion. Additional characteristics of suitable composite filaments and other form factors are specified below.

Composite filaments and other form factors obtained by melt blending may include the piezoelectric particles dispersed within the polymer material or a portion thereof. By virtue of the compatibilizing interactions, the piezoelectric particles may become uniformly dispersed within at least a portion of the polymer material. The compatibilizing interactions may further allow the piezoelectric particles to become dispersed preferentially (localized) in one portion of the polymer material compared to another. For example, if the piezoelectric particles are compatibilized with a first thermoplastic polymer or polymer precursor but not a second thermoplastic polymer or polymer precursor, the piezoelectric particles may become substantially localized in the first thermoplastic polymer or polymer precursor, particularly if the second thermoplastic polymer or polymer precursor is immiscible with the first thermoplastic polymer or polymer precursor. A crosslinked polymer formed from a polymer precursor within the polymer material, if present, may be disposed in the same location as the piezoelectric particles or in a different location, depending on whether the piezoelectric particles are further covalently crosslinked or otherwise compatibilized with the crosslinked polymer. Localization of the piezoelectric particles in the foregoing manner may increase the effective piezoelectric particle concentration in the composites and may enhance the piezoelectric response obtained therefrom after poling.

Suitable melt blending processes may include melt mixing with stirring, followed by extrusion of the resulting melt blend, or direct blending via extrusion with a twin-screw extruder. The piezoelectric particles may or may not become compatibilized with at least one thermoplastic polymer during the melt blending process. Such melt blending processes followed by further extrusion may afford a good distribution of the piezoelectric particles within the resulting composite and printed parts obtained therefrom. Cryo-milling, grinding or shredding before further extrusion of the composite may further facilitate the extrusion process and further promote distribution of the piezoelectric particles within the polymer material. Preferably, the melt blending processes may be conducted without the combination of the polymer material and the piezoelectric particles ever being exposed to a solvent together, which may otherwise result in trace organic solvents remaining in the composites following extrusion in some instances, and undesirably become incorporated within a printed part. Moreover, melt blending with little to no void formation in the composites may be realized even in the absence of surfactants and other surface compatibilizers, which otherwise may be detrimental to include in a printed part. Further surprisingly and advantageously, little or no agglomeration of the piezoelectric particles within the polymer material may occur following melt blending, which may desirably improve the piezoelectric properties obtained after poling. A uniform distribution of individual piezoelectric particles in the polymer material or a portion thereof may be realized in some instances, wherein the piezoelectric particles remain above a percolation threshold concentration within the polymer material. The piezoelectric particles may be considered above a percolation threshold concentration if the piezoelectric particles communicate with one another to generate a voltage when a mechanical load is being applied to the composites.

Advantageously, high loadings of piezoelectric particles may be tolerated in the composites described herein, while still maintaining extrudability and affording printed parts having high structural integrity and with the piezoelectric particles remaining in a substantially non-agglomerated and dispersed state following printing. Distribution of the piezoelectric particles as individuals rather than as agglomerates may afford a significant increase in the piezoelectric response obtained after poling, since there may be a greater particle surface area available to undergo interaction with the polymer material and promote load transfer in between. This effect may be further supplemented through compatibilization between the piezoelectric particles and the polymer material according to the disclosure herein.

Composite filaments compatible with fused filament fabrication may be formed in the disclosure herein. Although composite filaments may be an advantageous and particularly versatile form factor, it is to be realized that composite pellets may also be produced through melt blending processes and used in similar additive manufacturing processes. Namely, a polymer material comprising at least one thermoplastic polymer and piezoelectric particles may be combined with one another under melt blending conditions, and instead of extruding to form composite filaments, larger extrudates may be produced, which may then be cut, shredded, pulverized, or the like to afford composite pellets of a specified size and geometry or composite powders having even smaller dimensions and a wide distribution of particle sizes. Other than having a different shape, the microscopic morphology of the composite pellets may be similar to that of composite filaments. Like composite filaments, composite pellets and composite powders may be subsequently processed into printed parts having piezoelectric properties under suitable additive manufacturing conditions.

In the disclosure herein, “filaments” are to be distinguished from “fibers” on the basis that filaments comprise a single elongate form factor, whereas fibers comprise multiple filaments twisted together (bundled) to form a fine thread or wire in which the individual filaments remain identifiable. As such, filaments have smaller diameters than do fiber bundles formed therefrom, assuming no filament compression takes place when forming a fiber bundle. Filaments obtained by solution electrospinning or melt electrospinning are usually up to about 100 m in diameter, which is too small to be effectively printed using fused filament fabrication. The composite filaments obtained by melt blending and extrusion in the disclosure herein, in contrast, may be about 0.5 mm or more in size and dimensioned for compatibility with a particular printing system for fused filament fabrication.

Another suitable form factor that may be produced in the disclosure herein is an extrudable composite paste. As used herein, the term “paste” refers to a composition that is at least partially fluid at a temperature of interest. The term “paste” does not necessarily imply an adhesive function of any type. Moreover, the terms “paste” and “ink” may be used interchangeably with one another in the disclosure herein with respect to direct writing additive manufacturing processes. Unlike composite filaments and composite pellets discussed in brief above, extrudable composite pastes may comprise at least one solvent to facilitate extrusion. The polymer material may be at least partially dissolved or suspended in the at least one solvent, along with suspended piezoelectric particles, with a compatibilizing interaction between the polymer material and the piezoelectric particles occurring upon formulation or printing of the extrudable composite paste. Alternately, a polymer material compatibilized with piezoelectric particles may be pre-processed into composite particles (e.g., by melt blending and decreasing the particle size) that are then suspended or emulsified together in the solvent. The at least one solvent may or may not dissolve the polymer material present therein. Optionally, suitable composite pastes may be at least biphasic and contain at least two immiscible fluid phases, wherein the polymer material containing compatibilized piezoelectric particles are present in one or both of the at least two immiscible fluid phases. Localization of at least the piezoelectric particles in one phase or at an interface between polymer phases may increase the piezoelectric response attainable therefrom, since the effective concentration of the piezoelectric particles is increased. Additional details regarding extrudable composite pastes are also provided hereinbelow.

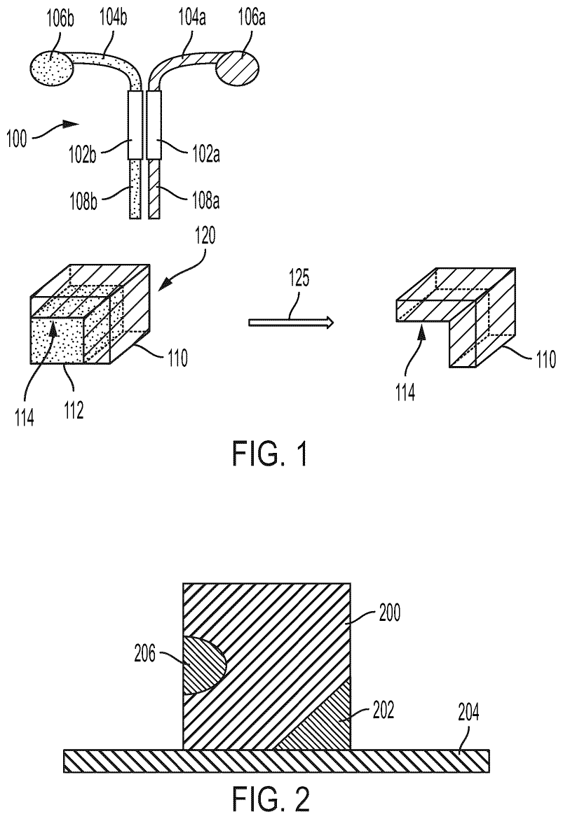

Before addressing various aspects of the present disclosure in further detail, a brief discussion of additive manufacturing processes, particularly fused filament fabrication processes, will first be provided so that the features of the present disclosure can be better understood. FIG. 1 shows a schematic of an illustrative fused filament fabrication process for producing a part using a build material and a removable support material. As shown in FIG. 1, print head 100 includes first extruder 102a and second extruder 102b, which are each configured to receive a filamentous printing material. Specifically, first extruder 102a is configured to receive first filament 104a from first payout reel 106a and provide molten stream 108a of a first printing material, and second extruder 102b is configured to receive second filament 104b from second payout reel 106b and provide molten stream 108b of a second printing material. Both molten streams are initially deposited upon a print bed (not shown in FIG. 1) to promote layer-by-layer growth of supported part 120. The first printing material (build material) supplied by first extruder 102a may be a piezoelectric composite of the present disclosure used to fabricate part 110, and the second printing material (removable support material) supplied by second extruder 102b may be a dissolvable or degradable polymer, which is used to fabricate removable support 112 under overhang 114. Overhang 114 is not in direct contact with the print bed or a lower printed layer formed from the build material. Overhang 114 need not necessarily be present in a given printed part. In the part arrangement shown in FIG. 1, removable support 112 is interposed between overhang 114 and the print bed, but it is to be appreciated that in alternatively configured parts, removable support 114 may be interposed between two or more portions of part 110. FIG. 2, for example, shows illustrative part 200, in which removable support 202 is interposed between an overhang defined between part 200 and print bed 204, and removable support 206 is interposed between two portions of part 200.

Referring again to FIG. 1, once printing of part 110 and removable support 112 is complete, supported part 120 may be subjected to support removal conditions 125 that result in elimination of removable support 112 (e.g., dissolution or disintegration conditions, or the like) and leave part 110 with overhang 114 unsupported thereon. Support removal conditions 125 may include contact of supported part 120 with a solvent in which removable support 112 is dissolvable or degradable and part 110 is not.

If a printed part is being formed without an overhang or similar feature, it is not necessary to utilize a removable support material during fabrication of the printed part. Similarly, two or more different build materials may be utilized as well, such as when one or more of the build materials is structural in nature and one or more of the build materials is functional in nature. In non-limiting examples, a structural polymer may be concurrently printed with a piezoelectric composite of the present disclosure. Further disclosure directed to such piezoelectric composites is provided herein.

Compositions of the present disclosure may comprise a polymer material comprising at least one thermoplastic polymer, at least one polymer precursor, or any combination thereof, and plurality of piezoelectric particles dispersed in at least a portion of the polymer material. The piezoelectric particles 1) interact non-covalently with at least a portion of the polymer material by π-π bonding, hydrogen bonding, electrostatic interactions stronger than van der Waals interactions, or any combination thereof, 2) are covalently bonded to at least a portion of the polymer material, 3) are reactive with at least a portion of the polymer material to form at least one covalent bond thereto under specified conditions, or 4) any combination thereof. The polymer material and the foregoing compatibilizing interactions may be selected to maintain the compositions in an extrudable state and capable of forming a self-standing three-dimensional structure upon being extruded. Examples of suitable piezoelectric particles and thermoplastic polymers effective for undergoing compatibilizing interactions of the foregoing types are provided below. The piezoelectric particles may be dispersed within the polymer material or a portion thereof in a uniform or non-uniform manner, such as a gradient distribution. In addition, at least a portion of the polymer material may not contain piezoelectric particles at all, such that the piezoelectric particles are concentrated in a particular polymer phase.

In various embodiments, the polymer material may comprise at least one thermoplastic polymer, wherein the piezoelectric particles are covalently bonded to the at least one thermoplastic polymer, are reactive with the at least one thermoplastic polymer under the specified conditions, interact non-covalently with the at least one thermoplastic polymer, or any combination thereof. Optionally, the polymer material may further comprise at least one polymer precursor, wherein the piezoelectric particles are reactive with the at least one polymer precursor, or a polymerized form thereof, under the specified conditions to form a covalent bond thereto, including covalent crosslinking of the piezoelectric particles to the polymer material. Optionally, the polymer material may further comprise at least one polymer precursor, wherein the piezoelectric particles are covalently bonded to the at least one polymer precursor. Suitable polymer precursors may comprise a polymerizable monomer or oligomer or a curable resin, examples of which are provided hereinbelow.

In some embodiments, the polymer material may comprise at least one thermoplastic polymer, in which the piezoelectric particles do not undergo a compatibilizing interaction with the at least one thermoplastic polymer or a portion thereof. In this case, the polymer material may further comprise at least one polymer precursor in which the piezoelectric particles are reactive with the at least one polymer precursor, or a polymerized form thereof, under the specified conditions (e.g., temperature, catalyst, initiator, etc.) to form a covalent bond thereto. Covalent bonding between the at least one polymer precursor or the polymerized form thereof may be a plurality of individual covalent bonds or a crosslinked network of covalent bonds. The covalent bonding may take place during or after depositing the compositions in a desired shape to form a printed part. Alternately or additionally, the piezoelectric particles may be covalently bonded to the at least one polymer precursor before polymerization or covalent crosslinking takes place.

The at least one thermoplastic polymer may comprise one thermoplastic polymer or more than one thermoplastic polymer. In the event that multiple thermoplastic polymers are present in the polymer material, a compatibilizing interaction may take place to each of the various thermoplastic polymers or only some of the thermoplastic polymers. Moreover, when multiple types of compatibilizing interactions are possible, a first thermoplastic polymer may interact with the piezoelectric particles via a first compatibilizing interaction and a second thermoplastic polymer may interact with the piezoelectric particles via a second compatibilizing interaction. In still another example, a first thermoplastic polymer may interact with the piezoelectric particles by a compatibilizing interaction, and a second thermoplastic polymer may not interact with the piezoelectric particles by a compatibilizing interaction. A portion of the at least one thermoplastic polymer, for example, may lack a functional group capable of promoting a compatibilizing interaction with a corresponding functional group upon the piezoelectric particles. When the first thermoplastic polymer and the second thermoplastic polymer are immiscible with one another, as discussed further below, the piezoelectric particles may become localized in a particular polymer phase by virtue of the compatibilizing interactions or lack thereof.

Optionally, the compositions may comprise at least one curable resin, typically in combination with at least one thermoplastic polymer in the polymer material. The at least one curable resin may be uniformly blended with the at least one thermoplastic polymer in the polymer material, or the at least one curable resin may be immiscible with the at least one thermoplastic polymer. The at least one curable resin may be curable by exposure to UV electromagnetic radiation or visible light (photocuring), thermal curing conditions, or any combination thereof to promote covalent crosslinking during or after formation of a printed part. Suitable examples of curable resins will be familiar to one having ordinary skill in the art, and illustrative examples are provided below. Photocuring may promote covalent crosslinking upon a surface portion of the printed part (e.g., up to a depth of about 50 microns or up to about 100 microns, depending on the electromagnetic radiation source used). Thermal curing may promote formation of a crosslinked polymer matrix throughout a printed part, especially given sufficient curing time, wherein the crosslinked polymer matrix is interblended with the at least one thermoplastic polymer. After covalent crosslinking takes place, the resulting crosslinked polymer and/or the at least one thermoplastic polymer may have piezoelectric particles covalently bonded thereto, or the crosslinked polymer and/or the at least one thermoplastic polymer may interact non-covalently with the piezoelectric particles.

As used herein, the term “thermally curable” means that a reaction occurs upon exposing a component to a specified threshold temperature above which the component becomes reactive, optionally in the presence of a thermal initiator that generates free radicals thermally and promotes a reaction of a thermally curable component, preferably such that one or more covalent crosslinking reactions take place. The specified threshold temperature may be any temperature above room temperature (25° C.); however, the specified threshold temperature is preferably about 50° C. or higher, or about 60° C. or higher, or about 70° C. or higher, or about 80° C. or higher, or about 90° C. or higher, or about 100° C. or higher, such as about 80° C. to about 120° C. or about 100° C. to about 150° C., or about 120° C. to about 180° C., or about 150° C. to about 200° C. Temperatures within these ranges may be compatible with melt blending techniques for forming the composites disclosed herein. As will be appreciated by one having ordinary skill in the art, the specified threshold temperature at which a particular component becomes covalently crosslinkable may vary based on several factors, such molecular structure and/or a thermal initiator used. However, the threshold temperature at which various components become reactive may either be well known or readily determined by a person having ordinary skill in the art.

When at least one curable resin is intended to undergo photocuring, at least one photoinitiator may be present in the compositions disclosed herein. Similarly, when the at least one curable resin is intended to undergo thermal curing, at least one thermal initiator may be present. Suitable examples of photoinitiators and thermal initiators will also be familiar to one having ordinary skill in the art. It is to be appreciated, however, that self-curable resins that are crosslinkable either under photocuring or thermal curing conditions are known and may be suitable for use in the disclosure herein.

Suitable photocurable and thermally curable resins may include reactive carbon-carbon double bonds, such as at least one (meth)acrylate compound. As used herein, the term “(meth)acrylate” refers to a compound derived from acrylic acid or methacrylic acid, in which a reactive carbon-carbon double bond is attached to the carbon atom adjacent to the acid derivative carbonyl group. Other types of photocurable resins that may be suitable for use in the disclosure herein include, for example, cyclic ethers, vinyl ethers, and certain types of heterocyclic compounds, all of which may be cationically initiated under irradiation. Other types of suitable thermally curable resins may include epoxy compounds, silicones, polyurethanes, phenolics, melamine formaldhyde resins, polyesters, urea formaldehyde resins, phenol formaldehyde resins, thioethers, thioesters, vinyl ester resins, cyanate ester resins, polybenzoxazines, polyimides, diallyl phthalate thermoset resins, furan resins, maleimide-based thermoset resins, vulcanized rubbers, and any combination thereof.

Suitable photocurable or thermally curable resins containing a (meth)acrylate moiety to promote curing include, for example, (meth)acrylated epoxy monomers or oligomers, (meth)acrylated ester monomers or oligomers, (meth)acrylated urethane monomers or oligomers, (meth)acrylated silicones, aminated (meth)acrylates, halogenated (meth)acrylate monomers or oligomers, aryl (meth)acrylates, aliphatic (meth)acrylates (including aliphatic ring (meth)acrylates), (meth)acrylated ethers, the like, and any combination thereof.

Another class of suitable thermally curable polymer precursors may include various epoxies, which may be one-component or two-component epoxies in various examples. General classes of epoxies include pure epoxies, epoxy acrylates, and polyester epoxies. Epoxies comprise a resin component (Component A) and a curing agent (Component B), which may be located within a single compound in a one-component epoxy. The resin component may comprise at least one epoxide functional group. Resins containing epoxide functional groups may include, for example, bisphenol A resins, cycloaliphatic resins, trifunctional or tetrafunctional epoxides, novolac-type resins, halogenated resins, fluorinated resins, bio-based epoxide resins, phosphorus-containing resins, silicon-containing resins, and the like. Common curing agents may include primary and secondary amines, alkaline substances (e.g., imidazoles and tertiary amines), anhydrides, and catalytic curing agents (e.g., benzylsulfonium salts, benzylpyridinium salts, benzylammonium salts, and phosphonium salts). More specific examples of suitable resins components and curing agents will be familiar to one having ordinary skill in the art.

Photoinitiators suitable for use in the disclosure herein are not believed to be particularly limited and may include any substance capable of forming free radicals upon being exposed to electromagnetic radiation. Example photoinitiators may include Norish Type I or Norish Type II photoinitiators including, but are not limited to, lithium phenyl-2,4,6-trimethylbenzoylphosphinate, ruthenium compounds, diphenyl(2,4,6-trimethylbenzoyl)phosphine oxide (IRGACURE), bis(2,4,6-trimethylbenzoyl)-phenylphosphineoxide (IRGACURE 819), 4-methylbenzophenone, 2,2-dimethoxy-2-phenylacetophenone (IRGACURE 651), hydroxycyclohexyl phenyl ketone (IRGACURE 184), hydroxycyclohexyl phenyl ketone:benzophenone 1:1 (IRGACURE 500), 2-hydroxy-2-methylpropiophenone (DAROCUR 1173α-hydroxy ketone), 2-hydroxy-4′-(2-hydroxyethoxy)-2-methylpropiophenone (IRGACURE 2959), methyl benzoylformate (DAROCUR MBF), blend of oxy-phenyl-acetic acid 2-[2-oxo-2-phenyl-acetoxy-ethoxy]-ethyl ester and oxy-phenyl-acetic acid 2-[2-hydroxy-ethoxy]-ethyl ester (OMNIRAD 754), (2-benzyl-2-(dimethylamino)-1-[4-(morpholinyl) phenyl)]-1-butanone) (IRGACURE 369), (2-methyl-4′-(methylthio)-2-morpholinopropiophenone) (IRGACURE 907), 2-benzyl-2-dimethylamino-1-(4-morpholinophenyl)-butanone-1:2,2-dimethoxy-1,2-diphenylethan-1-one 3:7 (IRGACURE 1300-α-aminoketone and benzildimethyl ketal), diphenyl (2,4,6-trimethylbenzoyl)-phosphine oxide (DAROCUR TPO), 2-hydroxy-2-methyl-1-phenyl-propan-1-one-2,4,6-trimethylbenzoyldiphenylphosphine oxide mixture (DAROCUR 4265), OMNIRAD 2022 (blend of IRGACURE 819 (20 wt. %)+DAROCUR 1173 (80 wt. %)), phosphine oxide (IRGAURE 2100), blend of iodonium, (4-methylphenyl)[4-(2-methylpropyl) phenyl]hexafluorophosphate (75%) in propylene carbonate (25%) (IRGACURE 250), bis(cyclopentadienyl)bis(2,6-difluoro-3-(1H-pyrro; 1-(2,4-Difluorophenyl)-1H-pyrrole titanium (IRGACURE 784). and the like. Other example of suitable photoinitiators will be familiar to one having ordinary skill in the art.

Thermal initiators suitable for use in the disclosure herein are not believed to be particularly limited and may include any substance capable of forming free radicals thermally upon exposure to a sufficient temperature. Example thermal initiators may include, but are not limited to, 2,5-di(t-butylperoxy)-2,5-dimethyl-3-hexyne and other peroxide or hydroperoxide compounds, azo compounds, or any combination thereof. Other example of suitable thermal initiators will be familiar to one having ordinary skill in the art and may include, for instance, 2,3-dimethyl-2,3-diphenylbutane, t-butyl hydroperoxide, 2,3-dimethyl-2,3-diphenylbutane, t-butyl hydroperoxide, t-amyl hydroperoxide, cumyl hydroperoxide, 1,1,3,3-tetramethylbutyl hydroperoxide, isopropylcumyl hydroperoxide, isopropylcumyl hydroperoxide, 2,5-dimethyl-2,5-di(tert-butylperoxy)-3-hexyne, 3,6,9-triethyl-3,6,9-trimethyl-1,4,7-triperoxonane, di(t-butyl)peroxide, 2,5-dimethyl-2,5-di(t-butylperoxy)hexane, di(tert-butylperoxy-isopropyl)benzene, t-butyl cumyl peroxide, di-(t-amyl)-peroxide, dicumyl peroxide, butyl 4,4-di(tert-butylperoxy)valerate, t-butylperoxybenzoate, 2,2-di(t-butylperoxy)butane, t-amyl peroxy-benzoate, t-butylperoxy-acetate, t-butylperoxy-(2-ethylhexyl)carbonate, t-butylperoxy isopropyl carbonate, t-butyl peroxy-3,5,5-trimethyl-hexanoate, 1,1-di(t-butylperoxy)cyclohexane, t-amyl peroxyacetate, and the like. Some examples of suitable thermal initiators may promote curing though mechanisms other than a free radical pathway.

In addition to forming a crosslinked polymer matrix, it is to be appreciated that curing may promote internal covalent crosslinking between the piezoelectric particles and/or between the crosslinked polymer and the piezoelectric particles, provided that the piezoelectric particles have been functionalized to include a crosslinkable functional group. A crosslinked polymer matrix formed from the curable resin may interpenetrate with at least one thermoplastic polymer once curing has taken place. The co-presence of at least one thermoplastic polymer and the crosslinked polymer matrix with interpenetration therebetween may aid in increasing the flexibility of a printed part, which may be advantageous in certain situations. In addition, load transfer may be facilitated as well.

Optionally, the compositions may further comprise at least one carbon nanomaterial dispersed in at least a portion of the polymer material. Suitable carbon nanomaterials for use in the disclosure herein may include, for example, exfoliated graphite, exfoliated graphite nanoplatelets, carbon nanofibers (CNF), carbon nanotubes (CNT), graphene, graphene oxides, reduced graphene oxides, graphite oxides, graphene oxide nanosheets, fullerenes, and the like. In particular examples, the carbon nanomaterials within the compositions disclosed herein may comprise a graphene, carbon nanofibers, carbon nanotubes, or any combination thereof. In some examples, the carbon nanomaterials may comprise at least one electrically conductive carbon nanomaterial, optionally in combination with one or more carbon nanomaterials that are not electrically conductive. Illustrative examples of electrically conductive carbon nanomaterials that may be present in the compositions disclosed herein include, for example, single-wall carbon nanotubes, multi-wall carbon nanotubes, carbon nanofibers, graphene, reduced graphene oxide, or any combination thereof. The carbon nanomaterials may be dispersed from one another as individual particles in the compositions disclosed herein. Optionally, the carbon nanomaterials (if present) may be covalently bonded to the at least one thermoplastic polymer and/or to the piezoelectric particles. Optionally, the carbon nanomaterials (if present) may be covalently crosslinked with themselves and/or with piezoelectric particles and/or with a crosslinked polymer after printing of the compositions has taken place.

Suitable graphenes, including graphene oxide, reduced graphene oxide, and the like, may include both single-layer and multi-layer graphene particles. Up to about 10 layers, up to about 20 layers, or up to about 30 layers, or up to about 40 layers, or up to about 50 layers, or up to about 60 layers of sp² hybridized carbon atoms may be present in multi-layer graphenes. Graphene particles may range from about 100 microns to about 1000 microns in size.

Graphene oxide is substantially an electrical insulator and may be produced through chemical exfoliation of graphite. Graphene oxide may be converted to reduced graphene oxide to at least partially restore electrical conductivity thereto. Suitable reducing agents for converting graphene oxide to a reduced graphene oxide include, for example, hydrogen and chemical reducing agents, as will be familiar to one having ordinary skill in the art.

Carbon nanotubes suitable for use in the disclosure herein may include single-wall carbon nanotubes, multi-wall carbon nanotubes or any combination thereof. Single-wall carbon nanotubes may have diameters ranging from about 1 nm to about 10 nm and may have a length to diameter ratio of about 1000 or above, such as about 1000 to about 10000, or about 1000 to about 5000. Multi-wall carbon nanotubes may comprise a plurality of single-wall carbon nanotubes nested within one another and may be up to about 100 nm in diameter for the outermost carbon nanotube.

Carbon nanofibers are larger in diameter than are carbon nanotubes and are usually longer in length. Suitable carbon nanofibers for use in the disclosure herein may include those having diameters ranging from about 100 nm to about 500 nm or about 100 nm to about 300 nm, and lengths ranging from about 5 microns to about 50 microns.

If present, the loading of carbon nanomaterials in the compositions disclosed herein may vary over a wide range, depending on whether the carbon nanomaterials have been introduced to facilitate load transfer or to provide electrical conductivity. When carbon nanomaterials are present in the compositions, the form factors may still remain extrudable and afford printed parts having high structural integrity. Although the electrical conductivity of certain carbon nanomaterials may facilitate poling, an excessive quantity of electrically conductive carbon nanomaterials may be avoided to lessen the likelihood of their promoting dielectric breakdown during the poling process.

When included, carbon nanomaterials may be present in the compositions described herein in an amount up to about 10 vol. % of the composite, or up to about 5 vol. %, or up to about 2 vol. %, or up to 1 vol. %, such as about 0.01 vol. % to about 0.1 vol. %, or about 0.05 vol. % to about 0.5 vol. %, or about 0.1 vol. % to about 0.5 vol. %, or about 0.2 vol. % to about 1 vol. %, or about 0.5 vol. % to about 2 vol. %, or about 1 vol. % to about 3 vol. %, or about 2 vol. % to about 4 vol. %. A maximum volume percentage of the carbon nanomaterials may be selected such that the composites do not experience significant dielectric breakdown during poling of a printed part.

Optionally, the piezoelectric particles may be covalently bonded with each other and/or interact non-covalently with each other, in addition to the piezoelectric particles undergoing a compatibilizing interaction with the polymer material. Suitable non-covalent interactions between the piezoelectric particles may include π-π bonding, hydrogen bonding, electrostatic interactions stronger than van der Waals interactions, or any combination thereof.

Non-covalent interactions resulting from π-π bonding may arise when two aromatic groups interact interfacially with each other. Thus, to produce a π-π noncovalent interaction between the polymer material and the piezoelectric particles (or between the piezoelectric particles), at least one aromatic group may be present upon at least a portion of the polymer material and the piezoelectric particles. Non-covalent interactions by π-π bonding can occur when the delocalized π-electron clouds of aromatic ring systems interact interfacially with one another, preferably extended aromatic ring systems containing two or more fused aromatic rings. The aromatic group upon piezoelectric particles undergoing π-π bonding may be directly attached to a surface of the particles or be appended by a linker moiety covalently attached to a surface of the particles. Linker moieties suitable for attaching an aromatic group to piezoelectric particles having hydroxyl groups upon a surface thereof may include, for example, silane-terminated or thiol-terminated linker moieties. Illustrative silane functionalities that can form a covalent bond with surface hydroxyl groups of piezoelectric particles may include, for example, alkoxysilanes, dialkoxysilanes, trialkoxysilanes, alkyldialkoxysilanes, dialkylalkoxysilanes, aryloxysilanes, diaryloxysilanes, triaryloxysilanes, silanols, disilanols, trisilanols, and any combination thereof. Aromatic groups suitable for promoting non-covalent interactions between a polymer material and piezoelectric particles may include, for example, phenyl, naphthalenyl, anthracenyl, phenanthrenyl, pyrenyl, benz(a)anthracenyl, tetracenyl, benzo[a]pyrenyl, benzo[e]pyrenyl, benzo(g,h,i)perylenyl, chrysenyl, and dibenz(a,h)anthracenyl. If not already present in a given type of polymer material, a co-monomer containing an aromatic group may be copolymerized with one or more non-aromatic monomers or grafted onto an existing polymer chain to produce a polymer suitable for promoting π-π bonding. Other types of groups that may bond covalently to the surface of piezoelectric particles for introducing various functionalities thereon, such as an aromatic group, include, for example, phosphines, phosphine oxides, phosphonic acids, phosphonyl esters, carboxylic acids, alcohols, and amines.

Non-covalent interactions resulting from hydrogen bonding may arise when a hydrogen bond donor and a hydrogen bond acceptor interact with each other. The hydrogen bond donor and the hydrogen bond acceptor may be located upon any combination of the piezoelectric particles and the polymer material in the disclosure herein. Hydrogen bond donors may include, for example, hydroxyl groups, amine groups, carboxylic acid groups, and the like. Hydrogen bond acceptors may include any oxygen atom or oxygen-containing functional group, any nitrogen atom or nitrogen-containing functional group, or a fluorine atom. If not already present upon the piezoelectric particles or the polymer material, suitable hydrogen bond donors or hydrogen bond acceptors may be introduced by one having ordinary skill in the art. Optionally, hydrogen bond donors or hydrogen bond acceptors may be introduced onto piezoelectric particles through a linker moiety using similar attachment chemistries to those discussed above.

Non-covalent interactions resulting from electrostatic interactions may arise when any combination of the piezoelectric particles and the polymer material have opposite charges interacting with each other (charge pairing or charge-charge interactions), including induced charge interactions in a dipole. Positively charged groups that may be present upon any of the piezoelectric particles or the polymer material may include, for example, protonated amines and quaternary ammonium groups. Negatively charged groups that may be present upon any of the piezoelectric particles or the polymer material may include, for example, carboxylates, sulfates, sulfonates, and the like. Like other types of non-covalent interactions, suitable groups capable of charge pairing may be introduced upon piezoelectric particles or a polymer material by one having ordinary skill in the art, including through attachment of a linker moiety to the piezoelectric particles. Other types of suitable electrostatic interactions may include, for example, charge-dipole, dipole-dipole, induced dipole-dipole, charge-induced dipole, and the like.

The compositions described herein are composites that are extrudable and may be in various form factors. In particular, the polymer material and the piezoelectric particles having a compatibilizing interaction therebetween may collectively define a composite that is extrudable and has a form factor selected from the group consisting of composite filaments, composite pellets, composite powders, and composite pastes. The piezoelectric particles may be mixed with the polymer material in any of these form factors, such as a substantially uniform dispersion of the piezoelectric particles in at least a portion of the polymer material. For example, when the piezoelectric particles are covalently bonded to the at least one thermoplastic polymer, the piezoelectric particles may be uniformly dispersed in the at least one thermoplastic polymer. If the polymer material comprises a thermoplastic polymer that is incapable of forming covalent bonds with the piezoelectric particles and/or a curable resin that is not crosslinkable with the piezoelectric particles, the piezoelectric particles may be non-uniformly dispersed in the polymer material as a whole while still being uniformly dispersed in the at least one thermoplastic polymer or another polymer phase to which the piezoelectric particles are covalently bound. Additional description of these form factors follows.

The polymer material or the piezoelectric particles may constitute a majority component of the composites disclosed herein. More preferably, the piezoelectric particles may comprise at least about 10 vol. %, or at least about 20 vol. %, or at least about 30 vol. %, or at least about 40 vol. %, or at least about 50 vol. %, or at least about 60 vol. %, or at least about 70 vol. %, or at least about 80 vol. %, or at least about 85 vol. %, or at least about 90 vol. %, or at least about 95 vol. % of the composites based on total volume. In more particular examples, the piezoelectric particles may comprise about 10 vol. % to about 85 vol. %, or about 25 vol. % to about 75 vol. %, or about 40 vol. % to about 60 vol. %, or about 50 vol. % to about 70 vol. % of the composite. A minimum volume percentage may be selected such that satisfactory piezoelectric properties are realized. A maximum volume percentage of the piezoelectric particles may be chosen such that the composite maintains structural integrity and extrudability. For example, in the case of composite filaments, the amount of piezoelectric particles may be chosen to maintain structural integrity as a continuous filament and that also remains printable by fused filament fabrication. Preferably, the piezoelectric particles may be distributed within the polymer material in a composite under conditions at which the piezoelectric particles remain substantially dispersed as individuals without becoming significantly agglomerated with each other. The piezoelectric particles may be de-agglomerated from each other prior to being combined with a polymer material, as discussed in further detail below.

Composite filaments of the present disclosure may be suitable for use in fused filament fabrication and include a polymer material comprising at least one thermoplastic polymer that is compatibilized with a plurality of piezoelectric particles dispersed therein. Optionally, the polymer material may further comprise at least one curable resin or other polymer precursor in combination with the at least one thermoplastic polymer. Further optionally, the at least one thermoplastic polymer may comprise one or more thermoplastic polymers that are not covalently bonded to the piezoelectric particles, including two or more thermoplastic polymers that are immiscible with one another. If present, the at least one curable resin may be curable by exposure to UV electromagnetic radiation or visible light (photocuring), thermal curing conditions, or any combination thereof to promote covalent crosslinking during or after forming a printed part. Photocuring may also take place with electromagnetic radiation such as gamma radiation, beta radiation, and electron beam radiation. The at least one curable resin may remain uncured until or after the compositions have been deposited layer-by-layer to form a printed part during an additive manufacturing process. In non-limiting examples, the composite filaments may be formed by melt blending, preferably such that the piezoelectric particles remain in a substantially non-agglomerated form following formation of the composite filaments. In various embodiments, the piezoelectric particles may be no more agglomerated than an extent of particle agglomeration prior to melt blending.

Composite pellets having distributed piezoelectric particles compatibilized with at least a portion of a polymer material may similarly be obtained by melt blending, in non-limiting examples. Instead of being produced in an elongate form similar to composite filaments, composite pellets may be characterized by an aspect ratio of about 5 or less and particle sizes having dimensions ranging from about 100 microns to about 5 cm. Composite pellets may feature loadings of piezoelectric particles and other optional components similar to those of composite filaments, and once printed and poled, they may provide a similar range of d₃₃ values. Similarly, the piezoelectric particles may remain in a substantially non-agglomerated form in the composite pellets produced according to the disclosure herein.

Composite powders may be obtained by grinding, milling, pulverizing, or similar processes to produce non-elongate particulates having an irregular shape and a particle size of about 10 microns to about 1 mm, or about 10 microns to about 500 microns, or about 10 microns to about 100 microns.

Extrudable composite pastes may comprise a plurality of piezoelectric particles having at least one compatibilizing interaction with a polymer material therein, and a sufficient amount of at least one solvent to promote extrusion at a temperature of interest. The extrudable composite pastes may be monophasic, biphasic, or triphasic. Alternately, extrudable composite pastes may omit a solvent if the polymer material comprises at least one curable resin or other polymer precursor having a sufficiently low viscosity to facilitate extrusion of the at least one thermoplastic polymer containing compatibilized piezoelectric particles. That is, the at least one curable resin may take the place of a solvent or replace a portion of a solvent when forming an extrudable composite paste according to the disclosure herein. When biphasic or higher, the piezoelectric particles and the polymer material may be present in one or both of the at least two immiscible phases. By virtue of the piezoelectric particles being compatibilized with at least one thermoplastic polymer, the piezoelectric particles may be present in at least the same phase where the at least one thermoplastic polymer is located. The polymer material and the piezoelectric particles may be processed into a composite, such as through melt blending and decreasing particle size as discussed above, wherein particles of the resulting pre-made composite are present in at least one phase of the extrudable composite paste. Alternately, a polymer material may be at least partially dissolved or suspended in at least one phase of an extrudable composite paste and piezoelectric particles may be suspended in another place of the extrudable composite paste, such that compatibilization between the piezoelectric particles and at least a portion of the polymer material may take place upon formulating the extrudable composite paste or as the extrudable composite paste is extruded into a desired shape when forming a printed part.

Optionally, the extrudable composite pastes may comprise a sol-gel material. When present, the sol-gel material may be included in an amount ranging from about 10 wt. % to about 20 wt. %, based on a combined mass of the extrudable composite paste. Inclusion of a sol-gel may result in a stiff matrix following curing, which may enhance the piezoelectric response obtained from the piezoelectric particles.

Suitable solvents that may be present in the extrudable composite pastes may include high-boiling solvents such as, but are not limited to, 1-butanol, 2-methyl-2-propanol, 1-pentanol, 3-methyl-1-butanol, 2,2-dimethyl-1-propanol, cyclopentanol, 1-hexanol, cyclohexanol, 1-heptanol, 1-octanol, propylene carbonate, tetraglyme, glycerol, 2-(2-methoxyethoxy)acetic acid or any combination thereof. Other high-boiling solvents having a boiling point in the range of about 100° C. to about 300° C. may be used as well. Suitable amounts of the at least one solvent may range from about 3 wt. % to about 35 wt. %, based on total mass of the extrudable composite paste.

In some embodiments, the extrudable composite pastes may be biphasic, in which case the at least one solvent may comprise water and a water-immiscible solvent. In non-limiting examples, an aqueous phase may comprise the water, a water-soluble polymer, and an immiscible organic phase may comprise a non-water soluble polymer material and an optional organic solvent. The piezoelectric particles may have a compatibilizing interaction between a thermoplastic polymer present within either the aqueous phase or the organic phase. When present, a sol-gel material may be present in the aqueous phase. The water-soluble polymer and the non-water soluble polymer material may be distributed co-continuously with one another, as described in more detail below.

The extrudable composite pastes may exhibit shear-thinning behavior, such that they may be readily extruded but quickly assume a fixed shape having a yield stress of about 100 Pa or greater upon being printed. In non-limiting examples, the extrudable composite pastes may have a viscosity of about 15,000 cP to about 200,000 cP when being sheared at a rate of about 5-10 s¹.

When produced from a suitable form factor, printed parts having good piezoelectric performance may be obtained following printing. More particularly, the composites of the present disclosure may be capable of being printed as a single-layer thin film having a d₃₃ value, after poling, of about 1 pC/N or more at a film thickness of about 200-500 microns, preferably about 200 microns, as measured using an APC International Wide-Range d₃₃ meter. Thin film thicknesses are measured using standard techniques separately from the d₃₃ measurements. In more particular examples, the composites may be capable of forming single-layer thin films having a d₃₃ value, after poling, of about 1 pC/N to about 400 pC/N, or about 2 pC/N to about 200 pC/N, or about 3 pC/N to about 100 pC/N, or about 1 pC/N to about 75 pC/N, or about 5 pC/N to about 50 pC/N, or about 1 pC/N to about 10 pC/N, or about 2 pC/N to about 8 pC/N, or about 3 pC/N to about 10 pC/N, or about 1 pC/N to about 5 pC/N, or about 4 pC/N to about 7 pC/N under these conditions. The loading of piezoelectric particles and suitable blending conditions to maintain the piezoelectric particles dispersed as individual particles within the polymer material may be selected to afford a desired extent of piezoelectricity. Single-layer film thicknesses that may be printable with the composites may range from about 10 μm to about 500 μm in thickness or about 25 μm to about 400 μm in thickness.

In order to display observable piezoelectric properties, a material such as a printed part or thin film, may be poled. Poling involves subjecting a material to a very high electric field so that dipoles of a piezoelectric material orient themselves to align in the direction of the applied field. Suitable poling conditions will be familiar to one having ordinary skill in the art. In non-limiting examples, poling may be conducted by corona poling, electrode poling or any combination thereof. In corona poling, a piezoelectric material is subjected to a corona discharge in which charged ions are generated and collect on a surface. An electric field is generated between the charged ions on the surface of a material and a grounded plane on the other side of the material. The grounded plane may be directly adhered to the material or present as a grounded plate. In the electrode poling (contact poling), two electrodes are placed on either side of a piezoelectric material, and the material is subjected to a high electric field generated between the two electrodes.

Although poling may be conducted as a separate step, as described above, poling may also be conducted in concert with an additive manufacturing process. In non-limiting examples, a high voltage may be applied between an extrusion nozzle supplying molten composite (formed from the composite filaments, composite pellets, or composite powders disclosed herein) and a grounded plane onto which the molten composite is being deposited to form a printed part.

Suitable piezoelectric particles for use in the present disclosure are not believed to be particularly limited, provided that the piezoelectric particles may be adequately blended with the polymer material and undergo a compatibilizing interaction with the polymer material, preferably remaining as individuals once blending with the polymer material has taken place. In the disclosure herein, the piezoelectric particles may be compatibilized through a reaction of native functional groups present upon the piezoelectric particles or a non-covalent interaction of the native functional groups, or the piezoelectric particles may be further functionalized with a linker moiety attaching a functional group that may achieve compatibilization with a complementary functional group upon the at least a portion of the polymer material, either covalently or non-covalently. Suitable examples of functional groups upon the piezoelectric particles and located within the polymer material are discussed in further detail below. In one example, surface hydroxyl groups upon the piezoelectric particles may be functionalized with a silane moiety having at least functional group that is reactive or interacts non-covalently with a complementary functional group located within the polymer material, such as at least one thermoplastic polymer. Other functionalization strategies for reacting native functional groups upon the surface of piezoelectric particles to introduce a suitable functional group for promoting a compatibilizing interaction according to the disclosure herein may be envisioned by one having ordinary skill in the art. Linker moieties attached to the surface of the piezoelectric particles, such as through the attachment chemistries discussed above, may also be utilized to introduce functional groups capable of experiencing a compatibilizing interaction with a complementary functional group upon the polymer material.

Illustrative types of covalent bonds that may be formed between the piezoelectric particles and the polymer material may include, but are not limited to, ethers, esters, amides, imides, carbon-carbon bonds, metal-ligand bonds, and the like. Other suitable examples will be familiar to one having ordinary skill in the art. Surface functional groups upon the piezoelectric particles and/or functional groups appended to the surface of the piezoelectric particles via a linker moiety may be utilized for forming the covalent bonds. Covalent bonding may involve covalent crosslinking between the piezoelectric particles and at least a portion of the polymer material in some instances. Crosslinking is to be distinguished from other types of covalent bonding in that a given piezoelectric particle may be covalently bonded to multiple polymer chains.

A functional group upon the piezoelectric particles may be suitable for promoting covalent bond formation. In non-limiting examples, the functional group upon the piezoelectric particles may comprise one of 1) a nucleophile or 2) an electrophile, and a complementary functional group upon the polymer material, such as within at least one thermoplastic polymer, may comprise the other of 1) a nucleophile or 2) an electrophile. Suitable nucleophiles that may be present upon the piezoelectric particles (either upon the particle surface or bonded through a linker moiety) or upon the polymer material may include, for example, alcohols, thiols, amines, carboxylates, and the like. Suitable electrophiles that may be present upon the piezoelectric particles (either upon the particle surface or bonded through a linker moiety) or upon the polymer material may include, for example, an alkyl halide, an epoxide, an acyl group (e.g., an aldehyde, a ketone, a carboxylic acid, a carboxylic acid anhydride (including cyclic anhydrides), a carboxylic acid chloride, and the like), an α,β-unsaturated carbonyl, a cyanate, an isocyanate, a thiocyanate, an isothiocyanate, and the like.

In some examples, the piezoelectric particles may include a nucleophile and the polymer material, such as at least one thermoplastic polymer, may comprise an electrophile that is reactive with the nucleophile upon the piezoelectric particles. In more specific examples, the polymer material may comprise a plurality of reactive groups (e.g., upon a side chain or as an end group) comprising a carboxylic acid or a carboxylic acid derivative that is reactive with a nucleophile located upon the piezoelectric particles. Still more specifically, the polymer material may comprise a plurality of reactive groups comprising an anhydride, a carboxylic acid, or any combination thereof, and the piezoelectric particles may be covalently bonded to the polymer material as a reaction product of at least a portion of the plurality of reactive groups. Suitable nucleophiles that may react with an anhydride group or a carboxylic acid group may include, for example, an amine (e.g., a primary or secondary amine) or an alcohol group. In the case of an amine being present upon the piezoelectric particles, the reaction product may comprise an amide. A cyclic anhydride upon the polymer material may form a cyclic imide upon reacting with an amine nucleophile upon the piezoelectric particles. In the case of an alcohol being present upon the piezoelectric particles, the reaction product may comprise an ester when reacted with a carboxylic acid or carboxylic acid derivative upon the polymer material.

It is to be recognized that all of the reactive groups upon the polymer material need not necessarily undergo a reaction to form a reaction product in the disclosure herein. Accordingly, a polymer material that is covalently bonded to (or reactive with) a piezoelectric particle may further include a plurality of unreacted reactive groups that have not reacted with piezoelectric particles. The loading of piezoelectric particles in the composites may dictate the extent of the reaction that occurs with the polymer material.

Illustrative examples of piezoelectric materials that may be present in piezoelectric particles suitable for use herein include, but are not limited to, crystalline and non-crystalline ceramics, and naturally occurring piezoelectric materials. Suitable crystalline ceramics exhibiting piezoelectric properties may include, but are not limited to, lead zirconate titanate (PZT), potassium niobate, sodium tungstate, Ba₂NaNNb₅O₅, and Pb₂KNb₅O₁₅. Suitable non-crystalline ceramics exhibiting piezoelectric properties may include, but are not limited to, sodium potassium niobate, bismuth ferrite, sodium niobate, barium titanate, bismuth titanate, and sodium bismuth titanate. Particularly suitable examples of piezoelectric particles for use in the disclosure herein may include those containing, for instance, lead zirconate titanate, doped lead zirconate titanate, barium titanate, lead titanate, strontium titanate, barium strontium titanate, lead magnesium niobate, lead magnesium niobate-lead titanate, sodium potassium niobate, calcium copper titanate, bismuth sodium titanate, gallium phosphate, quartz, toumarline and any combination thereof. Suitable dopants for lead zirconate titanate may include, but are not limited to Ni, Bi, La, and Nd.

Other suitable piezoelectric particles may include naturally occurring piezoelectric materials such as, for example, quartz crystals, cane sugar, Rochelle salt, topaz, tourmaline, bone, or any combination thereof. Still other examples of piezoelectric materials that may be used include, for example, ZnO, BiFO₃, and Bi₄Ti₃O₁₂.

The piezoelectric particles employed in the disclosure herein may have an average particle size in a micrometer or nanometer size range. In more particular examples, suitable piezoelectric particles may have a diameter of about 25 microns or less, or about 10 microns or less, such as about 1 micron to about 10 microns, or about 2 microns to about 8 microns. Smaller piezoelectric particles, such as those having an average particle size under 100 nm or an average particle size of about 100 nm to about 500 nm or about 500 nm to about 1 micron may also be utilized in the disclosure herein. Average particle sizes in the disclosure herein represent Dso values, which refers to a diameter at which 50% of the sample (on a volume basis unless otherwise specified) is comprised of particles having a diameter less than said diameter. Dso may also be referred to as the “average particle size.” Such average particle size measurements may be made by analysis of optical images, including via SEM analysis, or using onboard software of a Malvern Mastersizer 3000 Aero S instrument, which uses light scattering techniques for particle size measurement.

Agglomeration refers to an assembly comprising a plurality of particulates that are loosely held together through physical bonding forces. Agglomerates may be broken apart through input of energy, such as through applying ultrasonic energy, to break the physical bonds. Individual piezoelectric particles that have been produced through de-agglomeration may remain de-agglomerated once blending with a polymer material and compatibilization with a polymer material has taken place in the disclosure herein. That is, defined agglomerates are not believed to re-form during the blending processes with a polymer material as disclosed herein. It is to be appreciated that two or more piezoelectric particles may be in contact with one another in a melt-blended piezoelectric composite, but the extent of interaction is less than that occurring in an agglomerate of multiple piezoelectric particulates. In non-limiting examples, agglomerates of piezoelectric particles may have a size ranging from about 100 microns to about 200 microns, and individual piezoelectric particles obtained after de-agglomeration may be in a size range of about 1 micron to about 5 microns or about 1 micron to about 10 microns, or any other size range disclosed above. Particles under 1 micron in size (nanoparticles) may also be obtained in some instances. The de-agglomerated piezoelectric particle sizes may be maintained following formation of a composite having a form factor of the present disclosure.

Thermoplastic polymers suitable for use in the disclosure herein are not believed to be particularly limited, other than allowing piezoelectric particles to be sufficiently dispersed therein and bearing functionality suitable for undergoing a compatibilizing interaction with the piezoelectric particles according to the present disclosure. Covalent bonds may be formed before a suitable form factor of the composites has been deposited to form a printed part, or the covalent bond formation may be latent and occur during or after forming a printed part. In either case, the thermoplastic polymer may be a homopolymer or co-polymer containing at least one functional group suitable for undergoing a compatibilizing interaction with surface functionality upon piezoelectric particles or one or more functional groups appended to the surface of piezoelectric particles via a linker moiety. Covalent bond formation involving covalent crosslinking may occur during or after forming a printed part and take place using a curable resin, typically present in combination with at least one thermoplastic polymer, such as those discussed above.

In addition to facilitating distribution and covalent bonding of the piezoelectric particles, suitable thermoplastic polymers may exhibit a melting point or softening temperature compatible with extrusion. In non-limiting examples, suitable thermoplastic polymers may exhibit a softening temperature or melting point sufficient to facilitate deposition at a temperature ranging from about 50° C. to about 400° C., or about 70° C. to about 275° C., or from about 100° C. to about 200° C., or from about 175° C. to about 250° C. Melting points may be determined using ASTM E794-06 (2018) with a 10° C. ramping and cooling rate, and softening temperatures may be determined using ASTM D6090-17.

Illustrative examples of suitable thermoplastic polymers may include those commonly employed in fused filament fabrication such as, for instance, a polyamide, a polycaprolactone, a polylactic acid, a poly(styrene-isoprene-styrene) (SIS), a poly(styrene-ethylene-butylene-styrene) (SEBS), a poly(styrene-butylene-styrene) (SBS), a high-impact polystyrene (HIPS), polystyrene, a thermoplastic polyurethane, a poly(acrylonitrile-butadiene-styrene) (ABS), a polymethylmethacrylate, a poly(vinylpyrrolidine-vinylacetate), a polyester (e.g., polyethylene terephthalate (PET), polyethylene terephthalate glycol (PETG), polyethylene naphthalate (PEN), and the like), a polycarbonate, a polyethersulfone, a polyoxymethylene, a polyether ether ketone, a polyether aryl ketone, a polyetherimide, a polyethylene, a polyethylene oxide, a polyphenylene sulfide, a polypropylene, a polystyrene, a polyvinyl chloride, polyphenylene ethers (PPE), a poly(tetrafluoroethylene), a poly(vinylidene fluoride), a poly(vinylidene fluoride-hexafluoropropylene), any copolymer thereof, and any combination thereof.

Other suitable thermoplastic polymers that may be present in the compositions disclosed herein include, for example, polylactic acid, polyvinylpyrrolidone-co-polyvinyl acetate (PVP-co-PVA), copolymers thereof, and the like. Some examples of the composites disclosed herein may include a suitable thermoplastic polymer that is itself non-piezoelectric. In particular examples, some composites disclosed herein may comprise a thermoplastic polymer other than polyvinylidene fluoride.

If not already present in a given type of thermoplastic polymer, a functional group suitable for undergoing a compatibilizing interaction with a complementary functional group upon or appended to the piezoelectric particles may be introduced. When needed for promoting covalent bond formation to the piezoelectric particles, a co-monomer containing the functional group may be copolymerized with another monomer that is incapable of forming covalent bonds to the piezoelectric particles, or the functional group may be grafted onto an existing polymer chain. Accordingly, suitable copolymers for use in the disclosure herein may be any of random copolymers, block copolymers, alternating copolymers, graft copolymers, or any combination thereof. Graft copolymers may include copolymers in which a functional group suitable for reacting with the piezoelectric particles is directly appended to a main polymer chain, indirectly appended to a main polymer chain through a linker moiety defining a branch of the main polymer chain, or present within another polymer chain that is grafted as a branch onto the main polymer chain.

In more specific examples, any of the thermoplastic polymers listed above may include a grafted carboxylic acid or cyclic anhydride group, such as a grafted maleic anhydride group. In some embodiments, the at least one thermoplastic polymer forming a covalent bond to the piezoelectric particles may comprise a maleic anhydride-grafted polyolefin.

In another specific example, the terminal isocyanate groups of a polyurethane polymer may be utilized to form a covalent bond to piezoelectric particles bearing an amine group and/or with native surface functionality upon the piezoelectric particles.

In some embodiments, the polymer material within the composites may comprise a first polymer material and a second polymer material, wherein the first polymer material and the second polymer material are immiscible with each other, such as first and second thermoplastic polymers that are immiscible with one another. In some embodiments, the first polymer material may comprise one or more thermoplastic polymers that undergo a compatibilizing interaction with the piezoelectric particles, and the second polymer material may comprise one or more thermoplastic polymers that do not undergo a compatibilizing interaction with the piezoelectric particles. This situation may promote phase localization of the piezoelectric particles, as discussed in brief above.

A number of benefits and features may be realized by having a first polymer material and a second polymer material that are immiscible with one another. In some instances, the piezoelectric particles may be dispersed in one of the first polymer material or the second polymer material (e.g, the polymer material undergoing a compatibilizing interaction with the piezoelectric particles), thereby effectively increasing the local concentration of the piezoelectric particles in the composites. In some or other embodiments, one of the first polymer material and the second polymer material may be dissolvable or degradable under specified conditions, whereas the other of the first polymer material and the second polymer material is not. For example, a second polymer material that is not compatibilized with the piezoelectric particles may be removable from the first polymer material (e.g., through dissolution or degradation). Optionally, non-polymeric materials that are dissolvable or degradable may be utilized to accomplish a similar result. Upon dissolving or degrading one of the first polymer material or the second polymer material (or a non-polymeric dissolvable or degradable material that may be processed into an extrudable composite in combination with a polymer material), a composite having porosity defined therein may be realized. Optionally, the porosity may be backfilled with a material differing from the polymer material (or non-polymeric material) that was removed by degradation or dissolution. If the first polymer material and the second polymer material are distributed co-continuously, as discussed further below, a porous composite having a plurality of interconnected pores may be obtained. Alternately, a first polymer material and a second polymer material, in which neither polymer material is dissolvable or degradable, may be distributed co-continuously, optionally with piezoelectric particles substantially localized in one of the first polymer material or the second polymer material.

When porosity is introduced into a composite of the present disclosure, the porosity may be backfilled with material for further modifying the properties of the composite. In non-limiting examples, the porosity may by backfilled with electrically conductive particles including, but are not limited to, high-conductivity metal particles such as silver, copper, aluminum, gold, and the like; and electrically conductive carbon materials such as carbon black, carbon fibers, graphene, carbon nanotubes, and the like. Illustrative forms for electrically conductive particles may include, for example, nanoparticles, nanoflakes, nanowires, nanorods, microflakes, and the like. Additional materials that may be used for backfilling include, for example, a polymer differing from the polymer that was removed, thermally conductive particles, reinforcement fibers, colorants, stabilizers, plasticizers, the like, and any combination thereof. Such backfilling materials may be introduced in a liquid solution or dispersion, which is subsequently evaporated once backfilling has taken place. Alternately, a low viscosity polymer or low-viscosity curable resin may be utilized instead of a liquid solution or dispersion to promote delivery of the backfilling materials.

Other suitable materials for backfilling may include, for example, nanocrystalline cellulose, cellulose nanofibrils, silica, silica-alumina, alumina such as (pseudo)boehmite, gibbsite, titania, zirconia, cationic clays or anionic clays such as saponite, bentonite, kaoline, sepiolite, hydrotalcite, and the like. Other suitable backfilling materials may also include metal oxides such as alumina trihydrate (ATH), alumina monohydrate, magnesium hydroxide, magnesium silicate, talc, silicas such as fumed silica and precipitated silica, and calcium carbonate, calcium metasilicate, Wollastonite, Dolomite, Perlite, hollow glass spheres, kaolin, and the like. UV stabilizers such as titanium oxide, zinc oxide, benzophenones, benzotriazoles, aryl esters, sterically hindered amines, the like, and any combination thereof may also be present.

Composites of the present disclosure may comprise a continuous polymer phase comprising first and second polymer materials, such as first and second thermoplastic polymers, that are immiscible with one another, wherein one of the polymer materials is dissolvable or degradable and may be at least partially removed from the other polymer material under specified conditions, thereby introducing porosity to the composite or printed part formed therefrom. The piezoelectric particles may be distributed within the polymer material that is not removable or degradable by virtue of a compatibilizing interaction described herein. The term “continuous polymer phase” refers to the bulk phase in which the piezoelectric particles and optionally carbon nanomaterials are mixed in at least a portion of the polymer matrix. A continuous polymer phase may contain the first and second polymer materials distributed co-continuously or non-co-continuously within one another. In a co-continuous distribution of the first and second polymer materials, the first and second polymer materials may exist as separate, continuous polymer phases that are interblended with each other. That is, the first and second polymer materials may define an interpenetrating network of the polymer materials, wherein there is connectivity between at least a majority of the first polymer material and connectivity between at least a majority of the second polymer material throughout the continuous polymer phase. In a non-co-continuous distribution of the first and second polymer materials, in contrast, isolated pockets of one of the polymer materials may exist in a continuous matrix of the other. Thus, in a co-continuous distribution, any cross-section of the composite contains at least some of both the first polymer material and the second polymer material. Composites containing regions that are separately co-continuous or non-co-continuous also are within the scope of the present disclosure.

When two polymer materials are immiscible, removal of one of the polymer materials may afford controlled porosity or channel introduction into a printed part or a composite form factor used to produce a printed part. Very fine porosity features may be realized, much smaller than those that might be attainable through direct printing. In non-limiting examples, one of the polymer materials may be a water-soluble thermoplastic polymer and the other polymer material may be a water-insoluble thermoplastic polymer. In other instances, one of the polymer materials is dissolvable in an organic solvent and the other polymer material is not soluble in the same organic solvent (but may be soluble in a different organic solvent). In still other instances, one of the polymer materials may be degraded to byproducts that separate from the composite, wherein conditions promoting degradation do not impact the other polymer material. Degradation by melting which removes one of the polymer materials from the other also resides within the scope of the present disclosure. By altering the ratio of the immiscible polymer materials in the composite, the extent of porosity may be regulated to a desired degree. As indicated above, a non-polymeric material that is dissolvable or degradable under specified conditions may similarly be utilized to introduce porosity within a composite form factor or a printed part formed therefrom.

It is to be appreciated that the first polymer material and the second polymer material need not necessarily comprise a single polymer material of each type. Thus, depending on application-specific needs, the first polymer material may comprise one or more polymer materials, such as two or more thermoplastic polymers that are dissolvable or degradable under specified conditions, and the second polymer material may comprise one or more polymer materials, such as two or more thermoplastic polymers that are non-dissolvable or non-degradable under the specified conditions.

Advantageously, piezoelectric particles may remain substantially associated with or localized in the polymer material that remains undissolved or non-degraded by virtue of the compatibilizing interactions discussed herein, thus experiencing minimal loss when the dissolvable or degradable polymer material is removed (e.g., through exposure to an appropriate solvent or other conditions that may promote removal of one or more thermoplastic polymers in preference to another). Accordingly, a porous network of the piezoelectric particles distributed in the remaining polymer material (e.g., an insoluble or non-degradable thermoplastic polymer) may be realized after printing and further processing according to the disclosure herein. The porous network may comprise a plurality of interconnected pores. The piezoelectric particles and the carbon nanomaterials may be uniformly distributed in the remaining polymer material and have a higher effective concentration therein than in the as-produced composite.

Advantageously, composites capable of forming printed parts containing piezoelectric particles may be formulated using a room temperature aqueous-based process employing a water-soluble polymer. Polyvinyl alcohol (PVA), polyethylene glycol (PEG, also known as polyethylene oxide), or any combination thereof may be combined with piezoelectric particles in an aqueous phase containing a second polymer material (e.g., a second thermoplastic polymer) that is suspended in the aqueous phase and with which the water-soluble polymer is immiscible. After removal of the water from the combined aqueous phase, the two polymer materials may form a continuous polymer phase, in which the two polymer materials remain mutually immiscible with one another, and in which the piezoelectric particles are distributed throughout the continuous polymer phase while being substantially localized in the second polymer material (i.e., the water-insoluble thermoplastic polymer) or at an interface between the first polymer material and the second polymer material. In one example, the continuous polymer phase containing the piezoelectric particles may be obtained as a cast film before being processed into a final form factor, such as those specified above, wherein the piezoelectric particles are substantially localized within the second polymer material in the resulting composite form factors and printed parts formed therefrom. Therefore, once formed into a printed part, the first polymer material may be removed to afford a porous polymer network but without releasing substantial quantities of the piezoelectric particles and the optional carbon nanomaterials.

In some examples, the first polymer material may be a water-soluble thermoplastic polymer and the second polymer material may be a water-insoluble thermoplastic polymer. Examples of water-soluble thermoplastic polymers suitable for use in the disclosure herein may include, for example, polyvinyl alcohol, polyethylene glycol, any copolymer thereof, or any combination thereof. Some or other examples of suitable water-soluble thermoplastic polymers may include, but are not limited to, a polyvinylpyrrolidone, a polyoxazoline (e.g., poly(2-ethyl-2-oxazoline)), a cellulose ester, a polylactic acid, a polylactate, a polycaprolactone, any copolymer thereof, or any combination thereof. Solubility or degradation in aqueous acid solutions is also included within the scope of water solubility in the disclosure herein. Polylactic acid may be effectively degraded through contact with an aqueous acid. Polylactic acid may also be used effectively as non-degradable thermoplastic polymer in the disclosure herein (i.e., as a build material), provided that the composite or a printed part formed therefrom is only exposed to conditions chosen so as not to degrade the polylactic acid (i.e., non-acidic conditions). Similar considerations apply to polyesters like polycaprolactones, which may likewise be degradable under aqueous acid conditions but may be suitably used as a second polymer material if the first polymer material is removed under conditions that do not promote their degradation.

When a first polymer material and a second polymer material are combined to form a co-continuous phase, particularly a co-continuous phase containing a dissolvable or degradable thermoplastic polymer and a non-dissolvable or non-degradable thermoplastic polymer, containing piezoelectric particles, the ratio of the first polymer material to the second polymer material may vary over a wide range. In non-limiting examples, a ratio of the first polymer material to the second polymer material may range from about 1:99 to about 99:1 by volume. In more specific examples, the ratio of the first polymer material to the second polymer material may range from about 10:90 to about 90:10, or about 20:80 to about 80:20, or about 30:70 to about 70:30, or about 40:60 to about 60:40, or about 10:90 to about 20:80, or about 20:80 to about 30:70, or about 30:70 to about 40:60, or about 40:60 to about 50:50, or about 50:50 to about 60:40, or about 60:40 to about 70:30, or about 70:30 to about 80:20, or about 80:20 to about 90:10, each on a volume basis. The ratio of the first polymer material to the second polymer material may be selected such that a desired extent of flexibility is realized once a printed part is formed and the first polymer material is removed, or to tailor the extent of porosity formed in a printed part.

After removal of at least a portion of a first polymer material from a printed part, the printed parts may have a degree of porosity commensurate with the amount of the first polymer material that is removed. In non-limiting embodiments, the printed parts may have a porosity ranging from about 5% to about 80%, or about 10% to about 50%, or about 30% to about 70%, based upon the amount of mass removed relative to the total mass of a printed part prior to removal of the first polymer material. The pore size or the channel size of interconnected pores may depend upon the extent of dispersion of the first polymer material in the continuous polymer phase, as well as the amount of the first polymer material that is removed.

Once a first polymer material has been at least partially removed from a printed part, the piezoelectric particles may be present in a printed polymer matrix comprising the second polymer material (the remaining thermoplastic polymer) at a particle:polymer mass ratio of about 20:80 to about 97:3, based on total mass of the part following removal of the first polymer material. These values correspond to a particle:polymer volume percentage ranging from about 2 vol. % to about 80 vol. %.

By virtue of a compatibilizing interaction between piezoelectric particles and a polymer material according to the disclosure herein, at least a majority of the piezoelectric particles may be localized in a given portion of a continuous polymer phase defining the composite. The extent of localization within the polymer material may be determined based upon the amount of piezoelectric particles lost upon dissolution or degradation of the first polymer material. The piezoelectric particles may be distributed substantially as individuals in the polymer material. In non-limiting examples, at least about 80%, at least about 85%, at least about 90%, or at least about 95% of the piezoelectric particles originally blended with the continuous polymer phase may remain associated with the polymer material once another polymer material has been removed.

In fused filament fabrication processes utilizing composite filaments disclosed herein, the print head may contain one or more extruders, such that a first polymer filament comprising a build material is deposited from a first extruder. The build material may comprise a composite filament in accordance with the disclosure above. Optionally, a second polymer filament comprising a removable support material may be deposited from a second extruder to form a removable support for defining one or more overhangs in a printed part formed from the build material. Filaments (composite filaments or non-composite filaments) suitable for use in the foregoing manner may range from about 0.5 mm to about 10 mm in diameter, or about 1 mm to about 5 mm in diameter, particularly about 1.5 mm to about 3.5 mm in diameter. Standard filament diameters for many three-dimensional printers employing fused filament fabrication technology are 1.75 mm or 2.85 mm (about 3.0 mm). It is to be recognized that any suitable filament diameter may be used in accordance with the disclosure herein, provided that the filament is compatible with a user's particular printing system. Similarly, the length and/or color of the composite filaments is/are not believed to be particularly limited in the printing processes disclosed herein. Preferably, the composite filaments disclosed herein and utilized in processes for forming a printed part are continuous filaments and may be of spoolable length, such as at least about 1 foot, or at least about 5 feet, or at least about 10 feet, or at least about 25 feet, or at least about 50 feet, or at least about 100 feet, or at least about 250 feet, or at least about 500 feet, or at least about 1000 feet. The term “spoolable length” means sufficiently long to be wound on a spool or reel. It is to be appreciated that a composite filament of “spoolable length” need not necessarily be spooled, such as when the composite filament is too rigid to be wound onto a spool.

Accordingly, composite filaments produced according to the disclosure herein may have a diameter and length compatible for use in fused filament fabrication additive manufacturing processes. Particularly suitable examples may include composite filament diameters ranging from about 1 mm to about 10 mm and a length compatible with a continuous printing process. Various filament processing conditions may be utilized to adjust the filament diameter, as explained hereinafter.

Suitable methods for forming composite filaments compatible with fused filament fabrication may take place through melt blending of a polymer material comprising at least one thermoplastic polymer and a plurality of piezoelectric particles combined therewith, which may include melt mixing with stirring, followed by extrusion, or direct extrusion with a twin-screw extruder. The piezoelectric particles may already be compatibilized with the at least one thermoplastic polymer prior to extrusion, or may become covalently bonded to the at least one thermoplastic polymer during this process. More specific melt blending methods may comprise combining at least one thermoplastic polymer and a plurality of piezoelectric particles, forming a melt comprising the thermoplastic polymer and the piezoelectric particles, blending the melt, optionally with stirring, to form a melt blend comprising the piezoelectric particles covalently bonded to the at least one thermoplastic polymer and distributed therein, and extruding the melt blend to form a composite filament comprising the piezoelectric particles dispersed in a substantially non-agglomerated form within the at least one thermoplastic polymer. Composite pellets of the present disclosure may be formed in a similar manner, but without extruding directly into a filament form. Instead, the composite may be extruded into a larger diameter fiber that may be cut, shredded, pulverized, ground, or the like to afford composite pellets having a similar morphology to the composite filaments.

In further embodiments, the melt blend may be additionally processed before extruding takes place (e.g., in instances where melt blending takes place prior to extrusion). In particular, the melt blend may be cooled and solidified (e.g., below the melting point or softening temperature of a thermoplastic polymer), and cryogenically milling the melt blend after solidifying and prior to extruding the melt blend. Cryogenic milling will be familiar to one having ordinary skill in the art and may be conducted to reduce the particle size of the melt blend with lower risk of localized heating of the thermoplastic polymer and/or the piezoelectric particles taking place and promoting degradation thereof. Although cryogenic milling may be advantageous, it is to be appreciated that non-cryogenic milling may also be conducted, or the melt blend may be extruded directly without being cooled and solidified first in alternative process variations. Shredding or grinding of the melt blend may also be conducted prior to extrusion as an alternative process variation. In some instances, composite pellets may likewise be obtained without proceeding through a secondary extrusion process.

In some or other embodiments, melt blending methods for forming composites may include de-agglomeration of a piezoelectric material. In particular, piezoelectric particles employed to form the melt blends may be obtained by probe sonication, specifically probe sonication of larger piezoelectric particles or agglomerates thereof, wherein the input of sonic energy promotes de-agglomeration and formation of a reduced particle size. In more specific examples, PZT particles or similar piezoelectric particles processed by probe sonication may have an average particle size of about 10 microns or less, such as a particle size ranging from about 1 micron to about 5 microns, or about 1 micron to about 2 microns. Even smaller piezoelectric particles may be produced in some instances. These piezoelectric particle sizes may be maintained in the composites disclosed herein, with the piezoelectric particles remaining in a substantially non-agglomerated form once blended with a polymer material to define a composite. Other suitable techniques for de-agglomerating piezoelectric particles may include homogenization, ball milling, or the like.

When present, carbon nanomaterials may similarly be de-agglomerated into substantially individual carbon nanomaterial particles by sonication. Other techniques for de-agglomerating carbon nanomaterials will also be familiar to persons having ordinary skill in the art.

In some embodiments, de-agglomerated piezoelectric particles may be reacted with a linker moiety containing a functional group suitable for undergoing a compatibilizing interaction with a complementary functional group upon at least one thermoplastic polymer or other polymer material. In some embodiments, a bridging compound may facilitate covalent bond formation or a suitable type of non-covalent interaction between the piezoelectric particles and the polymer material. Suitable bridging compounds may be bifunctional and contain a first functional group that is reactive with the piezoelectric particles and a second functional group that is reactive with or interacts non-covalently with the polymer material, examples of which will be familiar to persons having ordinary skill in the art. Suitable examples of such complementary functional groups are provided above.

Additive manufacturing processes described herein may comprise providing a composition of the present disclosure, specifically a composite filament, a composite pellet, a composite powder, or a composite paste, and forming a printed part by depositing the composition layer-by-layer. Suitable layer-by-layer deposition techniques will be familiar to one having ordinary skill in the art and may be selected based upon the chosen form of the composite. In non-limiting examples, suitable layer-by-layer deposition techniques may include fused filament fabrication, direct writing, or any combination thereof. When the polymer material comprises at least one thermoplastic polymer, particularly when printing with composite filaments or composite pellets, the composition may be heated at or above a melting point or softening temperature of the at least one thermoplastic polymer when forming the printed part. Heating may facilitate the extrusion process taking place during the layer-by-layer additive manufacturing. Thus, once the at least one thermoplastic polymer cools, a printed part having a specified shape may be realized. When the polymer material comprises at least one curable polymer precursor, such as at least one curable resin, forming the printed part may further comprise curing the at least one curable polymer precursor to promote covalent crosslinking thereof. Covalent bond formation may also occur concurrently or after forming a printed part. Specifically, the polymer material may comprise at least one polymer precursor comprising a polymerizable monomer or a curable resin, and the additive manufacturing process may comprise exposing the printed part to conditions that polymerize the polymerizable monomer or oligomer or crosslink the curable resin. Curing may take place by, for example, exposure to thermal curing conditions or suitable electromagnetic radiation (photocuring), following formation of a printed part. Optionally, porosity may be introduced in a printed part through removal of a degradable polymer material, as discussed in further detail above. Poling at least a portion of the printed part may also take place to induce a piezoelectric response therein.

Embodiments disclosed herein include:
A. Compositions comprising piezoelectric particles. The compositions comprise: a polymer material comprising at least one thermoplastic polymer, at least one polymer precursor, or any combination thereof; and a plurality of piezoelectric particles dispersed in at least a portion of the polymer material; wherein the piezoelectric particles: 1) interact non-covalently with at least a portion of the polymer material by π-π bonding, hydrogen bonding, electrostatic interactions stronger than van der Waals interactions, or any combination thereof; 2) are covalently bonded to at least a portion of the polymer material; 3) are reactive with at least a portion of the polymer material to form at least one covalent bond thereto under specified conditions; or 4) any combination thereof; wherein the composition is extrudable and formable into a self-standing three-dimensional structure upon being extruded.
A1. Printed parts comprising the composition of A.
B. Additive manufacturing processes. The processes comprise: providing the composition of A; and forming a printed part by depositing the composition layer-by-layer.

Each of embodiments A, A1, and B may have one or more of the following additional elements in any combination:
Element 1: wherein the polymer material comprises at least one thermoplastic polymer, and the piezoelectric particles are covalently bonded to the at least one thermoplastic polymer, are reactive with the at least one thermoplastic polymer under the specified conditions, interact non-covalently with the at least one thermoplastic polymer, or any combination thereof.
Element 2: wherein the polymer material comprises at least one polymer precursor, and the piezoelectric particles are reactive with the at least one polymer precursor, or a polymerized form thereof, under the specified conditions to form a covalent bond thereto.
Element 3: wherein the at least one polymer precursor comprises a polymerizable monomer or oligomer or a curable resin.
Element 4: wherein the polymer material comprises at least one polymer precursor, and the piezoelectric particles are covalently bonded to the at least one polymer precursor.
Element 5: wherein the at least one polymer precursor comprises a polymerizable monomer or oligomer or a curable resin.
Element 6: wherein the polymer material further comprises at least one thermoplastic polymer.
Element 7: wherein the piezoelectric particles are covalently bonded to the at least one thermoplastic polymer, are reactive with the at least one thermoplastic polymer under the specified conditions, interact non-covalently with the at least one thermoplastic polymer, or any combination thereof.
Element 8: wherein the polymer material and the piezoelectric particles collectively define a composite having a form factor selected from the group consisting of a composite filament, a composite pellet, a composite powder, and a composite paste.
Element 9: wherein the piezoelectric particles are uniformly dispersed in at least a portion of the polymer material.
Element 10: wherein the piezoelectric particles comprise about 10 vol. % to about 85 vol. % of the composite.
Element 11: wherein the polymer material and the piezoelectric particles collectively define a composite filament.
Element 12: wherein the piezoelectric particles are substantially non-agglomerated when combined with the polymer material.
Element 13: wherein the piezoelectric particles have an average particle size of about 10 microns or less.
Element 14: wherein the piezoelectric particles comprise a piezoelectric material selected from the group consisting of lead zirconate titanate, doped lead zirconate titanate, barium titanate, strontium titanate, barium strontium titanate, lead titanate, lead magnesium niobate, lead magnesium niobate-lead titanate, sodium potassium niobate, calcium copper titanate, bismuth sodium titanate, gallium phosphate, quartz, tourmaline and any combination thereof.
Element 15: wherein the polymer material comprises at least one thermoplastic polymer.
Element 16: wherein the at least one thermoplastic polymer comprises a first thermoplastic polymer and a second thermoplastic polymer that are immiscible with each other.
Element 17: wherein the piezoelectric particles are substantially localized in one of the first thermoplastic polymer or the second thermoplastic polymer.
Element 18: wherein the first thermoplastic polymer and the second thermoplastic polymer collectively define a co-continuous polymer matrix.
Element 19: wherein a plurality of interconnected pores is present in the polymer material.
Element 20: wherein the composition further comprises a bridging compound that makes the piezoelectric particles reactive with the at least one thermoplastic polymer under the specified conditions.
Element 21: wherein the polymer material comprises at least one thermoplastic polymer, and the composition is heated at or above a melting point or softening temperature of the at least one thermoplastic polymer when forming the printed part.
Element 22: wherein the piezoelectric particles are covalently bonded to the at least one thermoplastic polymer, are reactive with the at least one thermoplastic polymer under the specified conditions, interact non-covalently with the at least one thermoplastic polymer, or any combination thereof
Element 23: wherein the polymer material comprises at least one polymer precursor comprising a polymerizable monomer or oligomer or a curable resin, the additive manufacturing process further comprising: exposing the printed part to conditions that polymerize the polymerizable monomer or oligomer or crosslink the curable resin.
Element 24: wherein the piezoelectric particles are reactive with the at least one polymer precursor, or a polymerized form thereof, under the specified conditions to form a covalent bond thereto.
Element 25: wherein at least a portion of the printed part is cured by exposure to electromagnetic radiation or thermal curing conditions.
Element 26: wherein the process further comprises poling at least a portion of the printed part.
Element 27: wherein the polymer material and the piezoelectric particles collectively define a composite filament, and forming the printed part comprises a fused filament fabrication process.

By way of non-limiting example, exemplary combinations applicable to A, A1, and B include, but are not limited to: one or more of 1-7, and 8; one or more of 1-7, and 9; one or more of 1-7, and 10; one or more of 1-7, and 11; one or more of 1-7, and 12; one or more of 1-7, and 13; one or more of 1-7, and 14; one or more of 1-7, and 15; one or more of 1-7, and 16; one or more of 1-7, 16 and 17; one or more of 1-7, 16 and 18; one or more of 1-7, and 19; one or more of 1-7, and 20; 8 or 11, and 9; 8 or 11, and 10; 8 or 11, and 12; 8 or 11, and 13; 8 or 11 and 14; 8 or 11, and 15; 8 or 11, and 16; 8 or 11, 16 and 17; 8 or 11, 16 and 18; 8 or 11, and 19; 8 or 11, and 20; 9 and 10; 9 and 11; 9 and 12; 9 and 13; 9 and 14; 9 and 15; 9 and 16; 9, 16 and 17; 9, 16, and 18; 9 and 19; 9 and 20; 10 and 11; 10 and 12; 10 and 13; 10 and 14; 10 and 15; 10 and 16; 10, 16, and 17; 10, 16, and 18; 10 and 19; 10 and 20; 11 and 12; 11 and 13; 11 and 14; 11 and 15; 11 and 16; 11, 16, and 17; 11, 16, and 18; 11 and 19; 11 and 20; 12 and 13; 12 and 14; 12 and 15; 12 and 16; 12, 16, and 17; 12, 16, and 18; 12 and 19; 12 and 20; 13 and 14; 13 and 15; 13 and 16; 13, 16, and 17; 13, 16, and 18; 13 and 19; 13 and 20; 14 and 15; 14 and 16; 14, 16, and 17; 14, 16, and 18; 14 and 19; 14 and 20; 15 and 16; 15, 16, and 17; 15, 16, and 18; 15 and 19; 15 and 20; 16 and 17; 16 and 18; 16 and 19; 16 and 20; 16, 17, and 19; 16, 18 and 19; 16, 17; and 20; 16, 18, and 20; and 19 and 20. With respect to B, any of the foregoing may be in further combination with one or more of 21, 22, 23, 24, 25, 26, or 27.

### Clauses of the Disclosure

The present disclosure is further directed to the following non-limiting embodiments:

Clause 1. A composition comprising:
a polymer material comprising at least one thermoplastic polymer, at least one polymer precursor, or any combination thereof; and
a plurality of piezoelectric particles dispersed in at least a portion of the polymer material;
   wherein the piezoelectric particles:
      1) interact non-covalently with at least a portion of the polymer material by π-π bonding, hydrogen bonding, electrostatic interactions stronger than van der Waals interactions, or any combination thereof;
      2) are covalently bonded to at least a portion of the polymer material;
      3) are reactive with at least a portion of the polymer material to form at least one covalent bond thereto under specified conditions; or
      4) any combination thereof;
   wherein the composition is extrudable and formable into a self-standing three-dimensional structure upon being extruded.
      Clause 2. The composition of clause 1, wherein the polymer material comprises at least one thermoplastic polymer, and the piezoelectric particles are covalently bonded to the at least one thermoplastic polymer, are reactive with the at least one thermoplastic polymer under the specified conditions, interact non-covalently with the at least one thermoplastic polymer, or any combination thereof.
      Clause 3. The composition of clause 1, wherein the polymer material comprises at least one polymer precursor, and the piezoelectric particles are reactive with the at least one polymer precursor, or a polymerized form thereof, under the specified conditions to form a covalent bond thereto.
      Clause 4. The composition of clause 3, wherein the at least one polymer precursor comprises a polymerizable monomer or oligomer or a curable resin.
      Clause 5. The composition of clause 1, wherein the polymer material comprises at least one polymer precursor, and the piezoelectric particles are covalently bonded to the at least one polymer precursor.
      Clause 6. The composition of clause 5, wherein the at least one polymer precursor comprises a polymerizable monomer or oligomer or a curable resin.
      Clause 7. The composition of any one of clauses 3-6, or the composition of clause 3, wherein the polymer material further comprises at least one thermoplastic polymer.
      Clause 8. The composition of clause 7, wherein the piezoelectric particles are covalently bonded to the at least one thermoplastic polymer, are reactive with the at least one thermoplastic polymer under the specified conditions, interact non-covalently with the at least one thermoplastic polymer, or any combination thereof.
      Clause 9. The composition of clause 7 or clause 8, or the composition of clause 7, wherein the polymer material and the piezoelectric particles collectively define a composite having a form factor selected from the group consisting of a composite filament, a composite pellet, a composite powder, and a composite paste.
      Clause 10. The composition of clause 9, wherein the piezoelectric particles are uniformly dispersed in at least a portion of the polymer material.
      Clause 11. The composition of clause 9 or clause 10, or the composition of clause 9, wherein the piezoelectric particles comprise about 10 vol. % to about 85 vol. % of the composite.
      Clause 12. The composition of any one of clauses 1-11, or the composition of clause 1, wherein the polymer material and the piezoelectric particles collectively define a composite having a form factor selected from the group consisting of a composite filament, a composite pellet, a composite powder, and a composite paste.
      Clause 13. The composition of any one of clauses 1-12, or the composition of clause 12, wherein the piezoelectric particles are uniformly dispersed in at least a portion of the polymer material.
      Clause 14. The composition of any one of clauses 1-13, or the composition of clause 12, wherein the piezoelectric particles comprise about 10 vol. % to about 85 vol. % of the composite.
      Clause 15. The composition of any one of clauses 1-14, or the composition of clause 1, wherein the polymer material and the piezoelectric particles collectively define a composite filament.
      Clause 16. The composition of any one of clauses 1-15, or the composition of clause 1, wherein the piezoelectric particles are substantially non-agglomerated when combined with the polymer material.
      Clause 17. The composition of any one of clauses 1-16, or the composition of clause 1, wherein the piezoelectric particles have an average particle size of about 10 microns or less.
      Clause 18. The composition of any one of clauses 1-16, or the composition of clause 1, wherein the piezoelectric particles comprise a piezoelectric material selected from the group consisting of lead zirconate titanate, doped lead zirconate titanate, barium titanate, strontium titanate, barium strontium titanate, lead titanate, lead magnesium niobate, lead magnesium niobate-lead titanate, sodium potassium niobate, calcium copper titanate, bismuth sodium titanate, gallium phosphate, quartz, tourmaline and any combination thereof.
      Clause 19. The composition of any one of clauses 1-18, or the composition of clause 1, wherein the polymer material comprises at least one thermoplastic polymer.
      Clause 20. The composition of clause 19, wherein the at least one thermoplastic polymer comprises a first thermoplastic polymer and a second thermoplastic polymer that are immiscible with each other.
      Clause 21. The composition of clause 20, wherein the piezoelectric particles are substantially localized in one of the first thermoplastic polymer or the second thermoplastic polymer.
      Clause 22. The composition of clause 20 or clause 21, wherein the first thermoplastic polymer and the second thermoplastic polymer collectively define a co-continuous polymer matrix.
      Clause 23. The composition of any one of clauses 1-22, or the composition of clause 1, wherein a plurality of interconnected pores is present in the polymer material.
      Clause 24. The composition of any one of clauses 1-23, or the composition of clause 1, further comprising:
a bridging compound that makes the piezoelectric particles reactive with the at least one thermoplastic polymer under the specified conditions.
   Clause 25. An additive manufacturing process comprising:
providing the composition of any one of clauses 1-6 or 19; and
forming a printed part by depositing the composition layer-by-layer.
   Clause 26. The additive manufacturing process of clause 25, wherein the polymer material comprises at least one thermoplastic polymer, and the composition is heated at or above a melting point or softening temperature of the at least one thermoplastic polymer when forming the printed part.
   Clause 27. The additive manufacturing process of clause 26, wherein the piezoelectric particles are covalently bonded to the at least one thermoplastic polymer, are reactive with the at least one thermoplastic polymer under the specified conditions, interact non-covalently with the at least one thermoplastic polymer, or any combination thereof.
   Clause 28. The additive manufacturing process of clause 25, wherein the polymer material comprises at least one polymer precursor comprising a polymerizable monomer or oligomer or a curable resin, the additive manufacturing process further comprising: exposing the printed part to conditions that polymerize the polymerizable monomer or oligomer or crosslink the curable resin.
   Clause 29. The additive manufacturing process of clause 28, wherein the piezoelectric particles are reactive with the at least one polymer precursor, or a polymerized form thereof, under the specified conditions to form a covalent bond thereto.
   Clause 30. The additive manufacturing process of clause 29, wherein at least a portion of the printed part is cured by exposure to electromagnetic radiation or thermal curing conditions.
   Clause 31. The additive manufacturing process of clause 28, wherein at least a portion of the printed part is cured by exposure to electromagnetic radiation or thermal curing conditions.
   Clause 32. The additive manufacturing process of clause 28, wherein the piezoelectric particles are covalently bonded to the at least one polymer precursor.
   Clause 33. The additive manufacturing process of any one of clauses 28-32, or the additive manufacturing process of clause 28, wherein the polymer material further comprises at least one thermoplastic polymer.
   Clause 34. The additive manufacturing process of any one of clauses 25-33, or the additive manufacturing process of clause 25, wherein the polymer material and the piezoelectric particles collectively define a composite having a form factor selected from the group consisting of a composite filament, a composite pellet, a composite powder, and a composite paste.
   Clause 35. The additive manufacturing process of any one of clauses 25-34, or the additive manufacturing process of clause 25, wherein the piezoelectric particles are uniformly dispersed in at least a portion of the polymer material.
   Clause 36. The additive manufacturing process of any one of clauses 25-35, or the additive manufacturing process of clause 25, wherein the piezoelectric particles are substantially non-agglomerated when combined with the polymer material.
   Clause 37. The additive manufacturing process of any one of clauses 25-36, or the additive manufacturing process of clause 25, wherein the piezoelectric particles have an average particle size of about 10 microns or less.
   Clause 38. The additive manufacturing process of any one of clauses 25-37, or the additive manufacturing process of clause 25, further comprising: poling at least a portion of the printed part.
   Clause 39. The additive manufacturing process of any one of clauses 25-38, or the additive manufacturing process of clause 25, wherein the polymer material and the piezoelectric particles collectively define a composite filament, and forming the printed part comprises a fused filament fabrication process.
   Clause 40. A printed part comprising the composition of any one of clauses 1-24, or the composition of clause 1.

To facilitate a better understanding of the present disclosure, the following examples of preferred or representative embodiments are given. In no way should the following examples be read to limit, or to define, the scope of the invention.

### EXAMPLES

Lead zirconate titanate (PZT, APC International, Ltd.) was sonicated using a Branson digital probe sonicator for 30 minutes in water at 25% amplitude to break up particle agglomerates. The original PZT agglomerate size of approximately 100 microns afforded PZT particles in a 1-5 micron size range following sonication, with a majority of the PZT particles being in a 1-2 micron size range. The PZT particles were dried at 80° C. overnight in a vacuum oven.

Alternately, a suspension of PZT particles in water (250 g PZT particles in 250 g water) was homogenized under high-shear conditions for 30 minutes using an IKA ULTRA-TURRAX T25 homogenizer. The PZT particles were isolated by centrifugation, washed with isopropanol, and dried at 80° C. in a vacuum oven overnight.

In some instances, the PZT particles were further functionalized upon their surface, as described in further detail below in Examples 1A-1C.

Shore A and Shore D hardness values were determined by a Shore D Rex Model DD-4 instrument according to ASTM S-2240, using the instantaneous instrument readout value.

For filament extrusion, samples were first shredded to afford a coarse powder, and the powder was then extruded using a single-screw Filabot FX6 extruder. The extruder was modified with a digital voltage readout to control the motor speed and extrusion rate. The Filabot EX6 filament extruder is capable of zonal temperature variation among the feed port nozzle, a back zone, a middle zone, and a front zone. The air path of the Filabot EX6 filament extruder may be further adjusted with respect to distance from the feed port nozzle or by raising the air path on a jack. The air path height was kept constant here, and 100% airflow was used, except as noted below. Measurement of the filament diameter was conducted using an inline thickness gauge.

Piezoelectric properties of printed and thermopressed samples were evaluated by measuring d₃₃ values using an APC International Wide-Range d₃₃ meter or a Piezotest PM300 Piezo meter. The d₃₃ meter is capable of measuring d₃₃ values between 1-2000 pC/N at an operating frequency of 110 Hz and an amplitude of 0.25 N. The d₃₃ value represents the quantity of charge generated when a piezoelectric material is subjected to a set applied force (amplitude).

Prior to making the d₃₃ measurements, all samples were poled by a corona poling method in which the sample was exposed to a corona discharge for times ranging from 2 to 60 minutes, but more typically 30 minutes. In the corona poling method, the sample was first coated with a thin layer of sputtered metal (Au, Pt, or Al) on one side of the sample, which was then exposed to a wire-generated corona (6-8 kV) located at a distance of about 1 mm from the sample. Since a surface area of approximately 300 μm² is exposed to the corona at a given time, the sample was moved to pole the complete surface through exposure to the corona. The poling process was not optimized. Contact poling in a high dielectric medium may be used as an alternative poling procedure.

Example 1A: Functionalization of PZT Particles with Phenyl Groups (PZT-Ph). Functionalization was conducted by combining 50 g PZT with 450 mL isopropanol and 50 mL deionized water in a 1000 mL beaker and sonicating with a probe sonicator in pulse mode with further magnetic stirring for 45 minutes. Pulsing was conducted at 50% amplitude in 1 second intervals, with a 0.5 second interval between pulses. Alternately, de-agglomeration may be conducted as above.

Following sonication, the mixture was transferred to a 1000 mL round bottom flask, and 25 g of N-(3-(trimethoxysilyl)propyl)aniline (TPA) was added. The reaction mixture was stirred overnight at room temperature and then heated to 80° C. for 3 hours with magnetic stirring. After cooling to room temperature, the functionalized PZT particles were isolated by centrifugation and washed twice with isopropanol. The functionalized PZT particles (PZT-Ph) were then dried at 60° C. overnight.

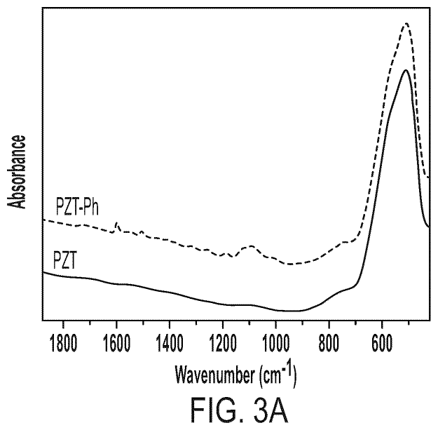

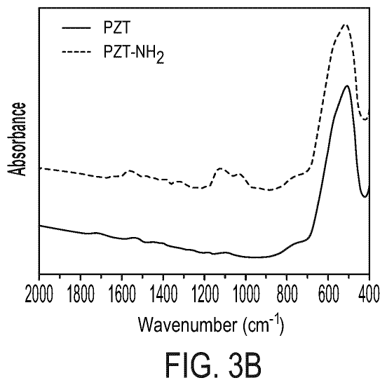

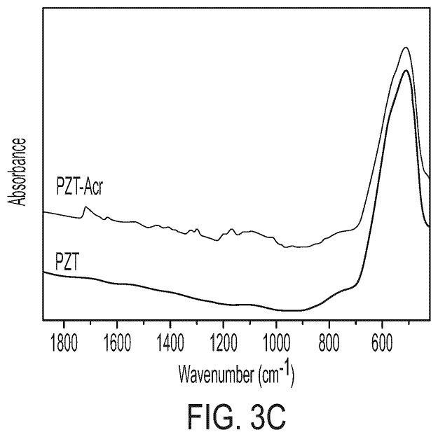

The PZT-Ph particles were further characterized by infrared spectroscopy, thermogravimetric analysis, and carbon/hydrogen/nitrogen analyses. Based upon these analyses the incorporation of N-(3-(trimethoxysilyl)propyl)aniline was determined at 2.6 wt. %, based on total mass (10.3 mmol silane per 100 g PZT particles). FIG. 3A is an illustrative overlay of FTIR spectra of PZT particles and PZT-Ph particles. As shown, the FTIR spectrum of unfunctionalized PZT particles was largely featureless, except for a large peak near 510 cm⁻¹, corresponding to metal-O-metal bonds. This peak was maintained in the FTIR spectrum of PZT-Ph particles, which also showed ingrowth of additional peaks at 1600 cm⁻¹, 1506 cm⁻¹, and 1093 cm⁻¹ corresponding to the appended phenyl group.

Example 1B: Functionalization of PZT Particles with Amino Groups (PZT-NH₂). Functionalization was conducted by combining 50 g PZT with 450 mL isopropanol and 50 mL deionized water in a 1000 mL beaker and sonicating with a probe sonicator in pulse mode with further magnetic stirring for 45 minutes. Pulsing was conducted at 50% amplitude in 1 second intervals, with a 0.5 second interval between pulses. Alternately, de-agglomeration may be conducted as above.

Following sonication, the mixture was transferred to a 1000 mL round bottom flask, and 25 g of aminopropyltriethoxysilane (APTES) was added. The reaction mixture was stirred overnight at room temperature and then heated to 80° C. for 3 hours with magnetic stirring. After cooling to room temperature, the functionalized PZT particles were isolated by centrifugation and washed twice with isopropanol. The functionalized PZT particles (PZT-NH₂) were then dried at 60° C. overnight.

The PZT-NH₂ particles were further characterized by infrared spectroscopy, thermogravimetric analysis, and carbon/hydrogen/nitrogen analyses. FIG. 3B is an illustrative overlay of FTIR spectra of PZT particles and PZT-NH₂ particles. As shown, the FTIR spectrum of unfunctionalized PZT particles was largely featureless, except for a large peak near 510 cm⁻¹, corresponding to metal-O-metal bonds. This peak was maintained in the FTIR spectrum of PZT-NH₂ particles, which also showed ingrowth of several additional smaller peaks at higher wavenumbers. Based upon these analyses, the incorporation of APTES was determined at 3.8 wt. %, based on total mass (16.9 mmol silane/NH₂ per 100 g PZT particles).

Example 1C: Functionalization of PZT Particles with Acrylate Groups (PZT-Acr). Functionalization was conducted by combining 50 g PZT with a mixture of 450 mL isopropanol and 50 mL deionized water in a 1000 mL beaker containing a magnetic stir bar. The mixture was sonicated with a probe sonicator under magnetic stirring for 45 minutes. Pulsing was conducted at 50% amplitude in 1 second intervals, with a 0.5 second interval between pulses. Alternately, de-agglomeration may be conducted as above.

Following sonication, the mixture was transferred to a 1000 mL round bottom flask, and 25 g of 3-(trimethoxysilyl)propyl methacrylate (TPM) was added. The reaction mixture was stirred overnight at room temperature and then heated to 80° C. for 3 hours with magnetic stirring. After cooling to room temperature, the functionalized PZT particles were isolated by centrifugation and washed twice with isopropanol. The functionalized PZT particles (PZT-Acr) were dried at 60° C. under vacuum overnight.

The PZT-Acr particles were further characterized by infrared spectroscopy, thermogravimetric analysis, and carbon/hydrogen/nitrogen analyses. Based upon these analyses the incorporation of 3-(trimethoxysilyl)propyl methacrylate was determined at 3.3 wt. %, based on total mass (13.4 mmol silane/methacrylate per 100 g PZT particles). FIG. 3C is an illustrative overlay of FTIR spectra of PZT particles and PZT-Acr particles. As shown, the FTIR spectrum of unfunctionalized PZT particles was largely featureless, except for a large peak near 510 cm⁻¹, corresponding to metal-O-metal bonds. This peak was maintained in the FTIR spectrum of PZT-Acr particles, which also showed ingrowth of additional peaks at 1715 cm⁻¹, 1634 cm⁻¹, and 1080 cm⁻¹ corresponding to the appended methacrylate group.

### Piezoelectric Composites Having Non-Covalent Compatibilizing Interactions

Functionalized and unfunctionalized PZT particles were blended with two different polyolefins having phenyl side chains. In one instance, the polymer was KRATON G1657 M, a linear triblock styrene/ethylene/butylene/styrene copolymer (SEBS) having a melt flow index (MFI) of 22 g/10 minutes (230° C./5 kg). In another instance, the polymer was KRATON D1162, a linear triblock styrene/isoprene/styrene copolymer (SIS) having a MFI of 45 g/10 mn (200° C./5 kg).

PZT particles were also functionalized in situ upon their surface with amine groups (PZT-NH₂) while blending with a polyamide, as described in further detail below in Example 4A.

Example 2A: Formation of a 40 vol. % PZT-Ph/SEBS Composite. PZT-Ph was combined with SEBS at 40 vol. %, based on total volume, and the resulting mixture was blended in a Haake compounder at 230° C. Blending was conducted by placing 27.3 g of SEBS pellets in the Haake compounder and melting under mixing conditions. 153.4 g PZT-Ph particles were then combined with the molten SEBS. After 10-15 minutes of blending, the mixture was discharged onto an aluminum pan and cooled to ambient temperature.

Comparative Example 2A: Formation of a 40 vol. % PZT/SEBS Composite. This composite was prepared as described for Example 2A, except 27.0 g SEBS and unsubstituted PZT particles were used.

Example 3A: Formation of a 40 vol. % PZT-Ph/SIS Composite. PZT-Ph was combined with SIS at 40 vol. %, based on total volume, and the resulting mixture was blended in a Haake compounder at 180° C. Blending was conducted by placing 27.6 g of SIS pellets in the Haake compounder and melting under mixing conditions. 153.4 g PZT-Ph particles were then combined with the molten SIS. After 10-15 minutes of blending, the mixture was discharged onto an aluminum pan and cooled to ambient temperature.

For filament fabrication, the resulting composite was first shredded to afford a coarse powder, and the powder was then extruded using a single-screw Filabot extruder.

Comparative Example 3A: Formation of a 40 vol. % PZT/SIS Composite. This composite was prepared as described for Example 3A, except unsubstituted PZT particles were used.

Example 4A: Formation of a 40 vol. % PZT-NH₂/Polyamide Composite. Amine-functionalized PZT (PZT-NH₂) was combined with a polyamide (Nylon-6, Sigma-Aldrich) at 40 vol. %, based on total volume, and the resulting mixture was blended in a Haake compounder at 230° C. Blending was conducted by placing 32.5 g of polyamide pellets in the Haake compounder and melting under mixing conditions. After melting occurred, 1.5 g of N-(2-aminoethyl)-3-aminopropyltrimethoxysilane was combined with the molten polyamide, and 153.4 g PZT particles were then added. After 10-15 minutes of blending, the mixture was discharged onto an aluminum pan and cooled to ambient temperature.

Comparative Example 4A: Formation of a 40 vol. % PZT/Polyamide Composite. This composite was prepared as described for Example 4A, except the N-(2-aminoethyl)-3-aminopropyltrimethoxysilane was omitted, thereby leaving the PZT particles unfunctionalized.

Shore Hardness. Table 1A summarizes the Shore Hardness values of selected samples produced above.

TABLE 1A

| Sample | Shore A Hardness | Shore D Hardness |
|---|---|---|
| Example 2A | 87.2 ± 1.2 | 35.5 ± 2.6 |
| Comparative Example 2A | 79.0 ± 0.6 | 25.9 ± 1.0 |
| Example 3A | 97.0 ± 1.3 | 46.1 ± 1.5 |
| Comparative Example 3A | 96.4 ± 0.3 | 48.9 ± 0.2 |

All samples containing piezoelectric particles exhibited higher Shore Hardness values than did the parent polymers (polymer-only data not shown). In the case of SEBS, functionalization of the PZT particles afforded higher values for both Shore A and Shore D Hardness, which may be indicative of increased non-covalent interactions between the polymer and the functionalized PZT particles. SIS-containing samples (Example 3A and Comparative Example 3A) did not exhibit significantly different Shore Hardness values, possibly due to the higher initial hardness of SIS alone.

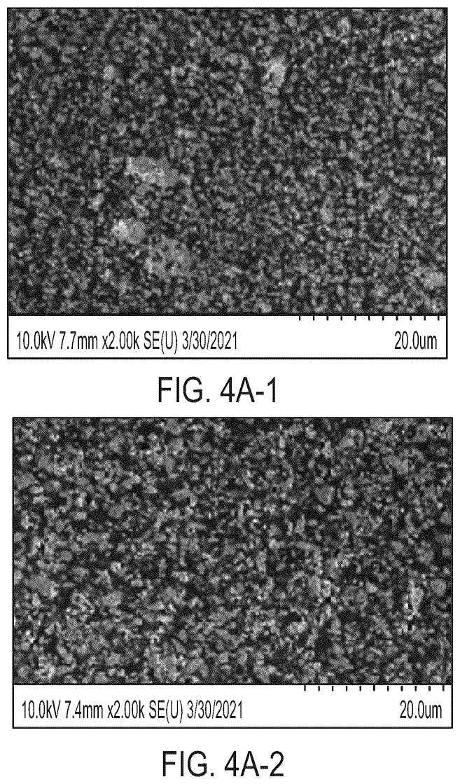

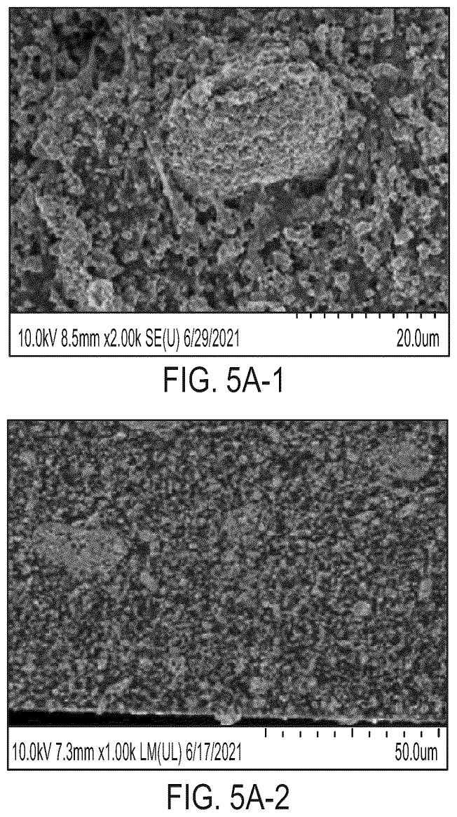

Imaging. The samples produced above were characterized by SEM imaging. FIGS. 4A-1 and 4A-2 show illustrative SEM images for the samples of Example 2A and Comparative Example 2A. FIGS. 5A-1 and 5A-2 show illustrative SEM images for the samples of Example 3A and Comparative Example 3A. In both cases, the samples containing PZT-Ph were more uniformly dispersed in the polymer (as evidenced by fewer dark spots in the SEM image).

Filament Extrusion. Table 2A below summarizes the extrusion conditions and filament properties obtained when preparing composite filaments from the composites of Examples 2A and 3A and Comparative Examples 2A and 3A.

TABLE 2A

| Feed Material | | | Comparative | | | | Comparative | |
|---|---|---|---|---|---|---|---|---|
| Source | Example 2A | | Example 2A | | Example 3A | | Example 3A | |
| Feed Temperature | 40° | C. | 40° | C. | 40° | C. | 40° | C. |
| Back Temperature | 190° | C. | 190° | C. | 180° | C. | 180° | C. |
| Middle | 200° | C. | 200° | C. | 180° | C. | 180° | C. |
| Temperature | | | | | | | | |
| Front | 200° | C. | 200° | C. | 180° | C. | 180° | C. |
| Temperature | | | | | | | | |
| Voltage | 4 | V | 15 | V | 10 | V | 10 | V |
| Nozzle size | 1.75 | mm | 1.75 | mm | 1.75 | mm | 1.75 | mm |
| Air flow | 100% | | 80% | | 100% | | 100% | |
| Average filament | 1.6-1.8 | mm | 1.6.1.8 | mm | 1.6-2.0 | mm | 1.6-1.7 | mm |
| diameter | | | | | | | | |

Printed Samples. The filaments made from Example 3A and Comparative Example 3A were printed as 20 mm squares of varying thicknesses using a Hyrel Hydra 16 A printer under the printing conditions specified in Table 3A below.

TABLE 3A

| Filament Material | | Comparative |
|---|---|---|
| Source | Example 3A | Example 3A |

| | | | | |
|---|---|---|---|---|
| Print Head | 1.75 | mm | 2.85 | mm |
| Nozzle | 0.5 | mm | 0.5 | mm |
| Extruder | 230° | C. | 230° | C. |
| Temperature | | | | |

| | | |
|---|---|---|
| Bed | Glass plate + | Glass plate |
| | DIMAFIX | |
| | adhesive | |

| | | | | |
|---|---|---|---|---|
| Bed Temperature | 70° | C. | 70° | C. |
| Print Speed | 10 | mm/s | 10 | mm/s |

Piezoelectric properties and additional characteristics of the printed samples are discussed further below.

Thermopressed Samples. The composites from Examples 2A-4A and Comparative Examples 2A-4A were also thermopressed into 20 mm squares of varying thicknesses using a Carver hydraulic press with the samples heated above their melting point or glass transition temperature in a mold. Piezoelectric properties and additional characteristics of the thermopressed samples are discussed further below.

Piezoelectric Properties. Description of printed or thermopressed samples and their piezoelectric properties are provided in Table 4A below.

TABLE 4A

| | | | Sample | Avg. d₃₃ |
|---|---|---|---|---|
| | | | Thickness | Value |
| Entry | Composite | Sample Type | (μm) | (pC/N) |
| 1 | Example 2A | Thermopressed | 200 | 11 |
| 2 | Comparative | Thermopressed | 180 | 6 |
| | Example 2A | | | |
| 3 | Example 3A | Printed | 370 | 3.4 |
| 4 | Example 3A | Thermopressed | 385 | 5.8 |
| 5 | Comparative | Printed | 320 | 0.3 |
| | Example 3A | | | |
| 6 | Comparative | Thermopressed | 530 | 4.0 |
| | Example 3A | | | |
| 7 | Example 4A | Thermopressed | 600 | 12.5 |
| 8 | Comparative | Thermopressed | 300 | 10.5 |
| | Example 4A | | | |

As shown, all samples containing PZT-Ph exhibited higher d₃₃ values than did the comparable comparative samples containing unfunctionalized PZT. This result implies that π-π interactions may increase d₃₃ values. Comparing Entries 7 and 8, it can be seen that when the piezoelectric particles are functionalized to include a group capable of donating or accepting hydrogen bonds and the polymer also contains a group capable of donating or accepting hydrogen bonds, increased d₃₃ values may be realized (Entry 7). The increased d₃₃ values of Entry 7 were observed despite this sample's larger thickness, which can decrease the poling efficiency.

### Piezoelectric Composites Having Covalent Compatibilizing Interactions

Further functionalized or native (unfunctionalized) PZT particles were blended with two different polyolefins having a functional group capable of forming covalent bonds with the piezoelectric particles. High density polyethylene (HDPE) with a MFI of 12 g/10 min (190° C./2.16 kg) (Sigma-Aldrich) or linear triblock styrene/ethylene/butylene/styrene copolymer (SEBS) having an MFI of 22 g/10 min (230° C./5 kg) (KRATON G1657 M) were used to prepare comparative piezoelectric composites lacking covalent bonding interactions between the polymer and the piezoelectric particles. HDPE grafted with maleic anhydride (HDPE-g-MA) having a maleic anhydride content of 1.0-1.5 wt. % and also with a MFI of 12 g/10 min (190° C./2.16 kg) (AMPLIFY GR 204, Dow Chemical Company) or a MFI of 4 g/10 mn (190° C., 2.16 kg) (Addivant), or SEBS grafted with maleic anhydride (SEBS-g-MA) having a maleic anhydride content of 1.4-2.0 wt. % and also with a MFI of 22 g/10 min (230° C./5 kg) (Kraton Polymer) were used to prepare experimental piezoelectric composites having covalent bonds between the polymer and the piezoelectric particles.

Example 2B (Comparative): Formation of a 40 vol. % PZT/HDPE Composite. PZT was combined with HDPE (MFI=12 g/10 min) at 40 vol. %, based on total volume, and the resulting mixture was blended in a Haake compounder at 190° C. Blending was conducted by placing 28.5 g of HDPE pellets in the Haake compounder and melting under mixing conditions. After the HDPE had melted, 153.4 g unfunctionalized PZT particles were then combined with the molten HDPE. After 10-15 minutes of additional blending, the mixture was discharged onto an aluminum pan and cooled to ambient temperature.

Example 3B-1: Formation of a 40 vol. % PZT/HDPE-g-MA Composite. This composite was prepared as described for Example 2B, except HDPE-g-MA (MFI=4 g/10 min) was used.

Example 3B-2: Formation of a 40 vol. % PZT/HDPE-g-MA Composite. This composite was prepared as described for Example 2B, except HDPE-g-MA (MFI=12 g/10 mn) was used.

Example 4B-1: Formation of a 40 vol. % PZT-NH₂/HDPE-g-MA Composite. This composite was prepared as described for Example 2B, except HDPE-g-MA (MFI=4 g/10 mn) and PZT-NH₂ were used.

Example 4B-2: Formation of a 40 vol. % PZT-NH₂/HDPE-g-MA Composite. This composite was prepared as described for Example 2B, except HDPE-g-MA (MFI=12 g/10 min) and PZT-NH₂ were used.

Example 5B (Comparative): Formation of a 40 vol. % PZT/SEBS Composite. This composite was prepared as described for Example 2B, except 27.0 g of SEBS pellets were used, and the blending temperature was 230° C.

Example 6B: Formation of a 40 vol. % PZT/SEBS-g-MA Composite. This composite was prepared as described for Example 2B, except 27.3 SEBS-g-MA pellets were used, and the blending temperature was 230° C.

Example 7B (Comparative): Formation of a 40 vol. % PZT/Polyurethane Composite. PZT was combined with a thermoplastic polyether polyurethane (ELASTOLLAN 1190A10, BASF) at 40 vol. %, based on total volume, and the resulting mixture was blended in a Haake compounder at 190° C. Blending was conducted by placing 33.9 g of polyurethane pellets in the Haake compounder and melting under mixing conditions. After melting occurred, 153.4 g of PZT particles were combined with the molten polyurethane. After 10-15 minutes of blending, the mixture was discharged onto an aluminum pan and cooled to ambient temperature.

Example 8B: Formation of a 40 vol. % PZT-NH₂/Polyurethane Composite (2 wt. % amine loading). This composite was prepared in a similar manner to Example 7B, except amine-functionalized PZT (PZT-NH₂) was formed and covalently bonded to unreacted urethane end groups of the polyurethane during blending. After forming molten polyurethane, 3.0 g of (2 wt. % with respect to PZT) of N-(2-aminoethyl)-3-aminopropyltrimethoxysilane was combined with the molten polyurethane and mixed for 2 minutes. Thereafter, 153.4 of unfunctionalized PZT particles were added, and after 10-15 minutes of blending, the mixture was discharged onto an aluminum pan and cooled to ambient temperature.

Example 9B: Formation of a 40 vol. % PZT-NH₂/Polyurethane Composite (1 wt. % amine loading). This composite was prepared in a similar manner to Example 8B, except 1.5 g of (1 wt. % with respect to PZT) of N-(2-aminoethyl)-3-aminopropyltrimethoxysilane was combined with the molten polyurethane.

Example 10B: Formation of a 40 vol. % PZT-NH₂/Polyurethane Composite (0.5 wt. % amine loading). This composite was prepared in a similar manner to Example 8B, except 0.8 g of (0.5 wt. % with respect to PZT) of N-(2-aminoethyl)-3-aminopropyltrimethoxysilane was combined with the molten polyurethane.

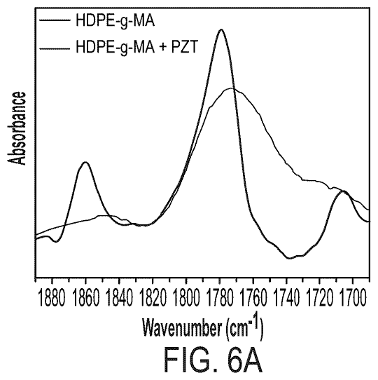

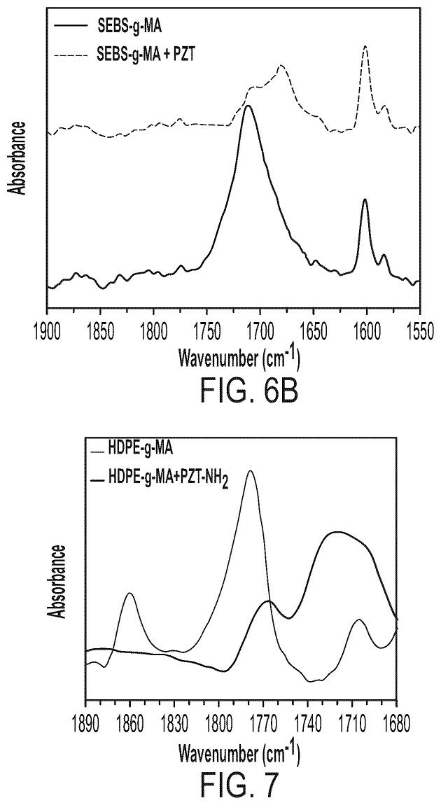

FTIR Characterization. Formation of a bonding interaction taking place between the unfunctionalized PZT particles and the cyclic anhydride group of the grafted maleic anhydride was evidenced by FTIR. FIG. 6A is a diagram showing overlaid FTIR spectra of HDPE-g-MA (MFI=12 g/10 min) and the composite of Example 3B-2. FIG. 6B is a diagram showing overlaid FTIR spectra of SEBS-g-MA and the composite of Example 6B. In both cases, the carbonyl peak(s) broadened and shifted to lower wavenumbers in the presence of the unfunctionalized PZT particles, indicating an interaction occurring between the two. The interaction is believed to be a covalent bond resulting from reaction of the anhydride with surface functional groups upon the PZT particles. Direct complexation of a metal ion (e.g., lead) within the PZT particle is also possible.

Formation of a bonding interaction between the functionalized PZT-NH₂ particles and the cyclic anhydride group of the grafted maleic anhydride was also evidenced by FTIR. FIG. 7 is a diagram showing overlaid FTIR spectra of HDPE-g-MA (MFI=12 g/10 min) and the composite of Example 4B-2. As shown, the carbonyl peaks broadened and shifted to lower wavenumbers in the presence of the PZT-NH₂ particles, indicating a bonding interaction between the two. The peak shifts were much more dramatic than in the case of unfunctionalized PZT particles (Example 3B-2). The peak shifts to lower wavenumbers are believed to be consistent with formation of a cyclic imide or an amide from the cyclic anhydride.

Shore Hardness. Table 1B summarizes the Shore Hardness values of selected samples produced in the examples above.

TABLE 1B

| | | Shore A | Shore D |
|---|---|---|---|
| Entry | Sample | Hardness | Hardness |
| 1 | HDPE | 96.9 ± 1.1 | 61.4 ± 0.6 |
| | (MFI = 12 g/10 min, Reference) | | |
| 2 | Example 2B | — | 72.0 ± 0.7 |
| | (MFI = 12 g/10 min, Comp.) | | |
| 3 | HDPE-g-MA | 97.8 ± 2.0 | 59.8 ± 0.7 |
| | (MFI = 12 g/10 min Reference) | | |
| 4 | Example 3B-1 | — | 73.0 ± 0.6 |
| | (MFI = 4 g/10 min, Exp.) | | |
| 5 | Example 4B-1 | — | 77.3 ± 1.0 |
| | (MFI = 4 g/ 10 min, Exp.) | | |
| 6 | SEBS (Reference) | 57.0 ± 1.1 | — |
| 7 | Example 5B (Comp.) | 79.0 ± 0.6 | — |
| 8 | SEBS-g-MA (Reference) | 79.7 ± 1.6 | — |
| 9 | Example 6B (Exp.) | 88.7 ± 1.1 | — |

As shown, HDPE and HDPE-g-MA reference polymers (Entries 1 and 3) exhibited similar hardness values, while SEBS-g-MA was considerably harder than the SEBS reference material (Entries 6 and 8). Upon incorporating PZT particles within the polymer to form a composite, all hardness values increased. Comparing Entries 4 and 5 against the HDPE reference materials (Entries 1 and 3) and a HDPE-PZT composite lacking the ability to form covalent bonds (Entry 2), covalent bonding increased hardness values still further. Covalent bond formation in Entry 5 appeared to increase the hardness slightly more so than when only unfunctionalized PZT particles were used in Entry 4. Comparing Entries 7 and 9, covalent bonding also increased the hardness of SEBS.

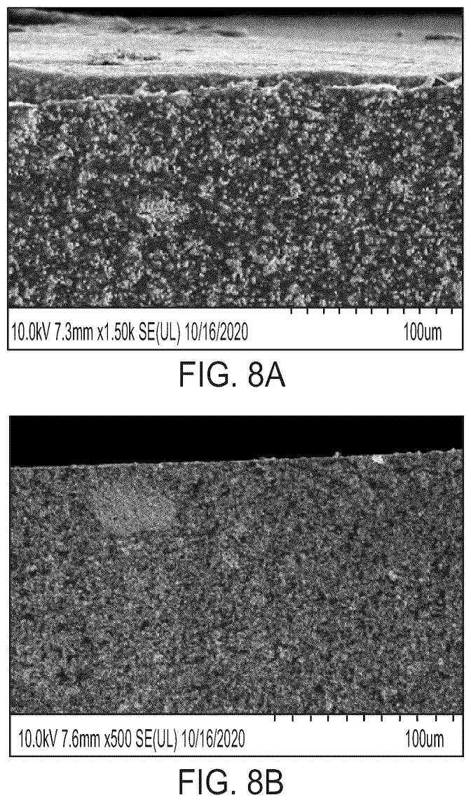

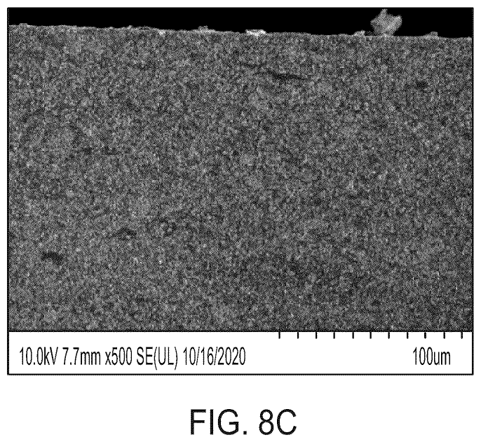

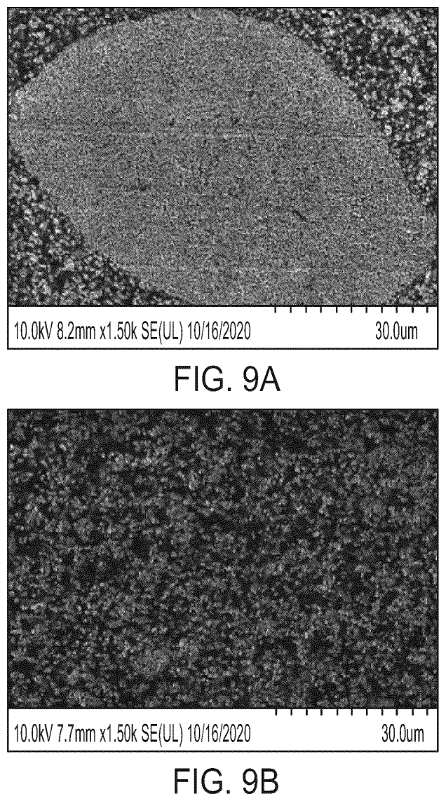

Imaging. The samples produced above were characterized by SEM imaging. FIGS. 8A-8C show illustrative SEM images for HDPE composites produced in Examples 2B, 3B-1, and 4B-2, respectively. FIG. 8A is an illustrative SEM image for the HDPE composite of Example 2B, in which covalent bonds are not possible between the PZT particles and the HDPE. FIGS. 8B and 8C are illustrative SEM images for HDPE-g-MA composites of Examples 3B-1 and 4B-2, respectively, in which unfunctionalized or functionalized PZT particles undergo covalent bonding with the HDPE-g-MA matrix. In both instances, the PZT particles were more evenly dispersed than when no covalent bonding was present, with functionalized PZT particles being even better dispersed than were unfunctionalized PZT particles. FIGS. 9A and 9B show illustrative SEM images for SEBS composites produced in Examples 5B and 6B, respectively. As shown, a more even distribution of PZT particles was observed in SEBS-g-MA compared to unfunctionalized SEBS.

Filament Extrusion. Table 2B below summarizes the extrusion conditions and filament properties obtained when preparing composite filaments from selected samples from above.

TABLE 2B

| Feed Material | Example 2B | | Example 3B-2 | | Example 6B | |
|---|---|---|---|---|---|---|
| Source | (Comp.) | | (Exp.) | | (Exp.) | |
| Feed Temperature | 60° | C. | 60° | C. | 40° | C. |
| Back Temperature | 190° | C. | 190° | C. | 190° | C. |
| Middle | 190° | C. | 190° | C. | 210° | C. |
| Temperature | | | | | | |
| Front | 170° | C. | 170° | C. | 210° | C. |
| Temperature | | | | | | |
| Voltage | 6.8 | V | 5.9 | V | 10 | V |
| Nozzle size | 2.0 | mm | 2.0 | mm | 1.75 | mm |
| Air flow | 100% | | 100% | | 100% | |
| Average filament | 1.6-1.7 | mm | 1.6-1.7 | mm | 1.6-1.7 | mm |
| diameter | | | | | | |

Printing. The filaments were printed using a Hyrel Hydra 16A 3D printer. Single and multiple layer structures were printed as 2 cm×2 cm squares for evaluation of piezoelectric properties of the composites. Each printed layer was ˜200 μm thick. Printing was performed onto a glass plate coated with a polypropylene release layer. During printing, the extrusion nozzle temperature was maintained at 200° C. and the glass plate was maintained at 100° C.

Piezoelectric Properties. Description of printed and thermopressed samples and their piezoelectric properties are provided in Table 4B below. Thermopressed samples of varying thicknesses were prepared as 20 mm squares of varying thicknesses using a Carver hydraulic press with the samples heated above their melting point or glass transition temperature in a mold.

TABLE 4B

| | | | | d₃₃ | d₃₃ |
|---|---|---|---|---|---|
| | | | Thickness | Thermopressed | Printed |
| Entry | Composite | Formulation | (μm) | (pC/N) | (pC/N) |
| 1 | Ex. 2B | HDPE (MFI = 12 | 100 | 1.8 | — |
| | (Comp.) | g/10 min)/40 vol. % PZT | 300 | — | 2.4 |
| | | | 500 | 0.2 | 1.2 |
| 2 | Ex. 3B-2 | HDPE-g-MA (MFI = 12 | 150 | 5.3 | 9.8 |
| | (Exp.) | g/10 min)/40 vol. % PZT | 500 | — | 7.0 |
| 3 | Ex. 4B-2 | HDPE-g-MA (MFI = 12 | 400 | 8.5 | — |
| | (Exp.) | g/10 min)/40 vol. % | | | |
| | | PZT-NH₂ | | | |
| 4 | Ex. 5B | SEBS/40 vol. % PZT | 400 | 6.5 | — |
| | (Comp.) | | | | |
| 5 | Ex. 6B | SEBS-g-MA/40 vol. % | 400 | 10.0 | — |
| | (Exp.) | PZT | | | |
| 6 | Ex. 7B | Polyurethane/40 vol. % | 500 | 5.5 | — |
| | (Comp.) | PZT | | | |
| 7 | Ex. 8B | Polyurethane/40 vol. % | 1000 | 5.5 | — |
| | (Exp.) | PZT (2 wt. % amine | | | |
| | | loading) | | | |
| 8 | Ex. 9B | Polyurethane/40 vol. % | 1000 | 4 | — |
| | (Exp.) | PZT (1 wt. % amine | | | |
| | | loading) | | | |
| 9 | Ex. 10B | Polyurethane/40 vol. % | 850 | 6.7 | — |
| | (Exp.) | PZT (0.5 wt. % amine | | | |
| | | loading) | | | |

As shown, unfunctionalized HDPE and SEBS produced relatively low d₃₃ values by virtue of their inability to form covalent bonds to the PZT particles. HDPE-g-MA and SEBS-g-MA composites exhibited higher d₃₃ values than did composites formed from the unfunctionalized polymers, even in thicker (˜500 micron) samples, which are sometimes more difficult to pole. Comparing Entries 2 and 3 against Entry 1, functionalized PZT-NH₂ particles afforded a slightly higher d₃₃ value than did unfunctionalized PZT in composites having comparable thicknesses. In addition, printed samples tended to exhibit higher d₃₃ values than did comparable thermopressed samples. The polyurethane samples (Entries 7-9), all exhibited comparable d₃₃ values to that of the comparative polyurethane sample (Entry 6), in spite of their considerably larger sample thickness.

### Piezoelectric Composites Containing a Crosslinked Polymer

For photoinitiated samples, functionalized and unfunctionalized PZT particles were blended with poly-ε-caprolactone (Mn=80,000, m.p.=60° C., Sigma-Aldrich) and aliphatic urethane acrylate oligomer CN9010 (Sartomer), as specified in the examples below. IRGACURE 651 (Ciba) was used as the photoinitiator.

For thermally initiated samples, functionalized and unfunctionalized PZT particles were blended with poly-ε-caprolactone, as specified in the examples below. The poly-ε-caprolactone sources and properties were as follows: 1) Mn=115,000 (Happy Wire Dog, LLC), and 2) Mn=70,000 (Scientific Polymer, Inc.). The polymer samples were formulated with either an aromatic urethane acrylate oligomer (CN935, Sartomer) or an aliphatic urethane acrylate oligomer CN9010 (Sartomer), as specified in the examples below. The thermal initiator was 2,5-di(t-butylperoxy)-2,5-dimethyl-3-hexyne (DBPDH, Sigma-Aldrich). The melting point of DBPDH is 88° C., and it has a thermal half-life of 10 hours at 131° C., 1 hour at 152° C., and 1 minute at 194° C.

Example 2C: Formation of a 40 vol. % PZT-Acr/PCL/Acrylate Composite Containing 10 wt. % Photoinitiator. PZT-Acr was combined with poly-ε-caprolactone (PCL) at 40 vol. %, based on total volume, and the resulting mixture was blended in a Haake compounder at 100° C. Blending was conducted by placing 23.9 g of PCL pellets in the Haake compounder and melting under mixing conditions. 10.8 g of aliphatic urethane acrylate oligomer CN9010 was added, and mixing was continued for 3 minutes. The ratio of PCL to acrylate oligomer was 2:1 on a volume basis. 153.4 g PZT-Acr particles were then combined with the molten mixture. After 10-15 minutes of blending, 1.08 g of IRGACURE 651 (10 wt. % of acrylate oligomer) was added and 5 additional minutes of mixing followed. The temperature was maintained below 120° C. at all times. After mixing was completed, the mixture was discharged onto an aluminum pan and cooled to ambient temperature. Shredding was then conducted with a SHR3D IT shredder (3devo).

Example 3C: Formation of a 40 vol. % PZT-Acr/PCL/Acrylate Composite Containing 20 wt. % Photoinitiator. This composite was prepared as described for Example 2C, except 22.8 g of PCL pellets, 12.0 g of acrylate oligomer, 153.4 g of PZT-Acr, and 2.4 g of IRGACURE 651 (20 wt. % of acrylate oligomer) were used.

Example 4C: Formation of a 60 vol. % PZT-Acr/PCL/Acrylate Composite Containing 10 wt. % Photoinitiator. This composite was prepared as described for Example 2C, except 15.2 g of PCL pellets, 8.0 g of acrylate oligomer, 230.0 g of PZT-Acr, and 0.8 g of IRGACURE 651 (10 wt. % of acrylate oligomer) were used. The temperature was maintained below 125° C. at all times due to an increased melt viscosity of this sample.

Example 5C (Comparative): Formation of a 40 vol. % PZT/PCL Composite. PZT was combined with poly-ε-caprolactone (PCL) at 40 vol. %, based on total volume, and the resulting mixture was blended in a Haake compounder at 100° C. Blending was conducted by placing 34.4 g of PCL pellets in the Haake compounder and melting under mixing conditions. 153.4 g of PZT particles (unfunctionalized) were then combined with the molten mixture. After 10-15 minutes of blending the mixture was discharged onto an aluminum pan and cooled to ambient temperature. Shredding was then conducted with a SHR3D IT shredder (3devo). The temperature was maintained below 115° C. at all times.

Example 6C: Formation of a 40 vol. % PZT/PCL/Acrylate Composite Containing 10 wt. % Photoinitiator. This composite was prepared as described for Example 2C, except 23.9 g of PCL pellets, 12.0 g of acrylate oligomer, 153.4 g of PZT, and 1.2 g of IRGACURE 651 (10 wt. % of acrylate oligomer) were used. The temperature was maintained below 121° C. at all times.

Example 2D: Formation of a 40 vol. % PZT/PCL/Acrylate Composite Containing 10 wt. % DBPDH Thermal initiator. PZT was combined with poly-$-caprolactone (PCL) (Scientific Polymer, Inc.) at 40 vol. %, based on total volume, and the resulting mixture was blended in a Haake compounder at 80° C. Blending was conducted by placing 22.8 g of PCL pellets in the Haake compounder and melting under mixing conditions. 11.8 g of aromatic urethane acrylate oligomer CN975 was added, and mixing was continued for 3 minutes. The ratio of PCL to acrylate oligomer was 2:1 on a volume basis. 153.4 g PZT particles (unfunctionalized) were then combined with the molten mixture. After 10-15 minutes of blending, 1.18 g of DBPDH thermal initiator (10 wt. % of acrylate oligomer) was added and 5 additional minutes of mixing followed. The temperature was maintained below 92° C. at all times. After mixing was completed, the mixture was discharged onto an aluminum pan and cooled to ambient temperature. Shredding was then conducted with a SHR3D IT shredder (3devo).

Example 3D: Formation of a 40 vol. % PZT/PCL/Acrylate Composite Containing a 10 wt. % DBPDH Thermal initiator. This composite was prepared as described for Example 2D, except an aliphatic urethane acrylate oligomer (CN9010, 12.0 g) was substituted for the aromatic acrylate oligomer, and 1.2 g of the DBPDH thermal initiator was used. The PZT particles were again unfunctionalized in this example. The temperature was maintained below 88° C. at all times.

Example 4D: Formation of a 40 vol. % PZT-Acr/PCL/Acrylate Composite Containing 10 wt. % DBPDH Thermal initiator. This composite was prepared as described for Example 3D, except PZT-Acr particles were used. The temperature was maintained below 91° C. at all times.

Example 5D (Comparative): Formation of a 40 vol. % PZT/PCL Composite. PZT was combined with poly-ε-caprolactone (PCL) (Happy Dog Wire, LLC) at 40 vol. %, based on total volume, and the resulting mixture was blended in a Haake compounder at 100° C. Blending was conducted by placing 34.4 g of PCL pellets in the Haake compounder and melting under mixing conditions. 153.4 g of PZT particles (unfunctionalized) were then combined with the molten mixture. After 10-15 minutes of blending the mixture was discharged onto an aluminum pan and cooled to ambient temperature. Shredding was then conducted with a SHR3D IT shredder (3devo). The temperature was maintained below 115° C. at all times.

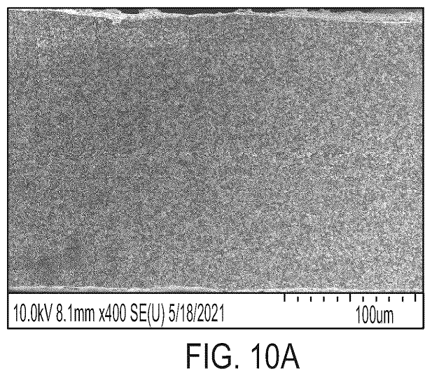

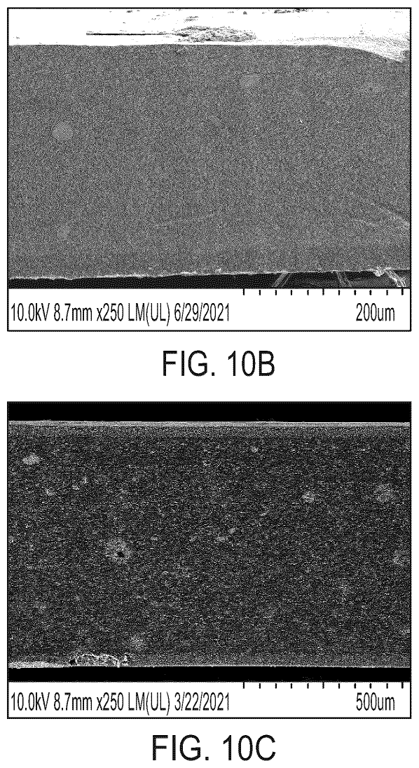

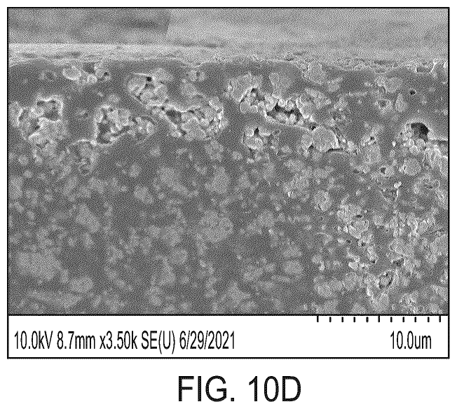

Imaging. The composite of Example 2C was thermopressed into samples of ˜500 micron thick disks using a Carver hydraulic press with the samples heated above their melting point or glass transition temperature in a mold. Samples were exposed to UV electromagnetic radiation on one or both sides of the disk using a 12 W Phoseon lamp (λ=395 nm). Exposure was conducted for 2 seconds with the electromagnetic radiation source located 6 cm from the disk. FIG. 10A shows an illustrative SEM image of a thermopressed disk containing the composite of Example 2C, in which the acrylate oligomer was uncured. FIGS. 10B and 10C show illustrative SEM images of thermopressed disks containing the composite of Example 2C, in which the acrylate oligomer was cured on one or both sides of the disk, respectively. The images of the cured samples (FIGS. 10B and 10C) showed distinct regions approximately 40 microns thick on each side where UV exposure took place, with uncured polymer matrix remaining within the interior of the samples. In addition, there was a greater extent of void formation upon the sample surfaces that were not cured, which is indicative of decreased interfacial adhesion between the polymer matrix and the PZT particles. FIG. 10D shows an illustrative SEM image of an uncured surface of a thermopressed disk containing the composite of Example 2C, in which the voids are readily evident.

The composite of Example 6C, in which the PZT particles were not acrylate functionalized, was also thermopressed and cured under similar conditions. SEM images (not shown) indicated a less uniform dispersion of the unfunctionalized PZT particles in the composite compared to that obtained when both the acrylate resin and the PZT particles were cured.

Filament Extrusion. Tables 2C and 2D below summarize the extrusion conditions and filament properties used when preparing composite filaments from selected samples from above.

TABLE 2C

| Feed Material | Example 2C | | Example 3C | | Example 5C | |
|---|---|---|---|---|---|---|
| Source | Experimental) | | (Experimental) | | (Comparative) | |
| Feed Temperature | 80° | C. | 30° | C. | 30° | C. |
| Back Temperature | 120° | C. | 120° | C. | 110° | C. |
| Middle | 120° | C. | 120° | C. | 110° | C. |
| Temperature | | | | | | |
| Front | 120° | C. | 100° | C. | 90° | C. |
| Temperature | | | | | | |
| Voltage | 20 | V | 8-12 | V | 22 | V |
| Nozzle size | 2.0 | mm | 1.75 | mm | 2.0 | mm |
| Air flow | 100% | | 100% | | 100% | |
| Average filament | 1.6-1.7 | mm | 1.6-1.7 | mm | 1.6-1.7 | mm |
| diameter | | | | | | |

TABLE 2D

| Feed Material | Example 1D | | Example 3D | | Example 4D | |
|---|---|---|---|---|---|---|
| Source | (Experimental) | | (Experimental) | | (Comparative) | |
| Feed Temperature | 30° | C. | 30° | C. | 30° | C. |
| Back Temperature | 90° | C. | 90° | C. | 110° | C. |
| Middle | 90° | C. | 90° | C. | 110° | C. |
| Temperature | | | | | | |
| Front | 90° | C. | 90° | C. | 90° | C. |
| Temperature | | | | | | |
| Voltage | 15 | V | 20 | V | 22 | V |
| Nozzle size | 1.75 | mm | 1.75 | mm | 2.0 | mm |
| Air flow | 100% | | 100% | | 100% | |
| Average filament | 1.4-1.6 | mm | 1.2-1.4 | mm | 1.6-1.7 | mm |
| diameter | | | | | | |

Printed Samples. The filaments made above were printed as 20 mm squares of varying thicknesses using a Hyrel Hydra 16 A printer under the printing conditions specified in Tables 3B and 3C below. The printed squares were cooled in a freezer (photocured samples) or room temperature (thermally cured samples) before removal from the glass plate.

TABLE 3B

| Filament Material | Example 2C | | Example 3C | | Example 5C | |
|---|---|---|---|---|---|---|
| Source | (Experimental) | | (Experimental) | | (Comparative) | |
| Nozzle | 0.5 | mm | 0.5 | mm | 0.5 | mm |
| Extruder Temperature | 200° | C. | 120° | C. | 200° | C. |
| Bed | Glass plate | | Glass plate | | Glass plate | |
| Adhesive | None | | None | | None | |
| Bed Temperature | 40° | C. | 45° | C. | 40° | C. |
| Print Speed | 20 | mm/s | 10 | mm/s | 20 | mm/s |

TABLE 3C

| | | |
|---|---|---|
| Filament Material | Example 1D | Example 3D |
| Source | (Experimental) | (Experimental) |

| | | | | |
|---|---|---|---|---|
| Nozzle | 0.5 | mm | 0.5 | mm |
| Extruder Temperature | 120° | C. | 120° | C. |

| | | |
|---|---|---|
| Bed | Glass plate | Glass plate |
| Adhesive | None | None |

| | | | | |
|---|---|---|---|---|
| Bed Temperature | 40° | C. | 40° | C. |
| Print Speed | 20 | mm/s | 20 | mm/s |

Piezoelectric properties, curing, and additional characteristics of the printed samples are discussed further below.

Piezoelectric Properties. Description of printed and thermopressed samples and their piezoelectric properties are provided in Tables 4C and 4D below. Thermopressed samples of varying thicknesses were prepared as 20 mm squares of varying thicknesses using a Carver hydraulic press with the samples heated above their melting point or glass transition temperature in a mold. The d₃₃ values were measured both before and after curing. Photocuring was conducted using a 12 W Phoseon lamp (λ=395 nm). Exposure was conducted for 1 second on both sides of the printed or thermopressed samples. Thermal curing was conducted by heating the samples at 200° C. for 5 minutes

TABLE 4C

| | | | | Avg. d₃₃ | Avg. d₃₃ |
|---|---|---|---|---|---|
| | | | Sample | Value- | Value- |
| | | | Thickness | uncured | cured |
| Entry | Composite | Sample Type | (μm) | (pC/N) | (pC/N) |
| 1 | Example 2C | Printed | 150 | 10.1 | 23.4 |
| | (Exp.) | | | | |
| 2 | Example 2C | Thermopressed | 500 | 7.5 | 20.8 |
| | (Exp.) | | | | |
| 3 | Example 3C | Thermopressed | 300 | 8 | 20.3 |
| | (Exp.) | | | | |
| 4 | Example 5C | Printed | 150 | 10.7 | n/a |
| | (Comp.) | | | | |
| 5 | Example 6C | Thermopressed | 750 | 6.5 | 11 |
| | (Exp.) | | | | |

TABLE 4D

| | | | | Avg. d₃₃ | Avg. d₃₃ |
|---|---|---|---|---|---|
| | | | Sample | Value- | Value- |
| | | | Thickness | uncured | cured |
| Entry | Composite | Sample Type | (μm) | (pC/N) | (pC/N) |
| 1a | Example 2D | Thermopressed | 700 | 5 | — |
| | (Exp.) | | | | |
| 1b | Example 2D | Thermopressed | 600 | — | 7 |
| | (Exp.) | | | | |
| 2a | Example 3D | Thermopressed | 500 | 3.7 | — |
| | (Exp.) | | | | |
| 2b | Example 3D | Thermopressed | 500 | — | 4.4 |
| | (Exp.) | | | | |
| 3a | Example 4D | Thermopressed | 700 | 5 | — |
| | (Exp.) | | | | |
| 3b | Example 4D | Thermopressed | 500 | — | 12 |
| | (Exp.) | | | | |
| 4 | Example 5D | Thermopressed | 500 | 4.5 | — |
| | (Comp.) | | | | |

For the photocurable samples, all cured samples exhibited higher d₃₃ values than did their uncured counterparts. Moreover, comparing the uncured d₃₃ values of Entries 1 and 4 against each other, unfunctionalized and functionalized PZT particles both produced similar d₃₃ values when the PZT particles were present at a similar volume percentage. Although crosslinking of the acrylate oligomer afforded some enhancement of the piezoelectric response (Entry 5), the increase was not as dramatic as when the sample also contained functionalized PZT particles (Entry 2) that are also curable. Thus, some enhancement of the piezoelectric response may be realized by having a crosslinked polymer incorporated within a matrix of the PCL, but further improvement of the piezoelectric response may be realized by crosslinking the piezoelectric particles to themselves and/or to the crosslinked polymer.

Similarly, for thermally curable samples, all cured samples exhibited higher d₃₃ values than did their uncured counterparts. When the PZT particles were also curable, the increase was greater than when only a thermally curable acrylate oligomer was present (comparing Entries 3a/b against Entries 1a/1b and Entries 2a/2b). Moreover, comparing the uncured d₃₃ values of Entries 1a, 2a, and 3a against Entry 4, it can be seen that unfunctionalized and functionalized PZT particles both produced similar d₃₃ values when the PZT particles were present at a similar volume percentage.

Mechanical Properties. Mechanical properties were measured for uncured and cured samples obtained by thermopressing the composite of Examples 2C, 2D, 3D, and 4D into a dogbone shaped mold similar to ISO Type 5 bars. Curing was conducted as above. The measurements were conducted using ASTM D638-14 Standard Test Method on an Instron 3367 instrument at a rate of 5 mm/min. Testing results are summarized in Tables 5A and 5B below.

TABLE 5A

Example 2C

| | Uncured | Cured |
|---|---|---|
| Young's Modulus (MPa) | 99 | 135 |
| Tensile Strength (MPa) | 3.9 | 4.1 |
| Elongation at Break (%) | >60% | 13 |

TABLE 5B

| | Example 2D | | Example 3D | | Example 4D | |
|---|---|---|---|---|---|---|
| | Uncured | Cured | Uncured | Cured | Uncured | Cured |
| Young's | 179 ± 23 | 1040 ± 48 | 66 ± 6 | 1180 ± 117 | 150 ± 10 | 1310 + 147 |
| Modulus | | | | | | |
| (MPa) | | | | | | |
| Tensile | 3.7 ± 0.2 | 19.5 ± 1.6 | 4.4 ± 0.2 | 17 ± 6 | 4.4 ± 0.6 | 23 ± 4 |
| Strength | | | | | | |
| (MPa) | | | | | | |
| Elongation | 3.4 ± 0.9 | sharp | 11.3 ± 0.2 | sharp | 5.6 ± 1.4 | sharp |
| at Break | | break | | break | | break |
| (%) | | | | | | |
| Nominal | 13.6 ± 3.6 | 3.1 ± 0.3 | >100 | 2.7 ± 0.6 | 14 ± 5 | 3.1 ± 0.5 |
| Strain at | | | | | | |
| Break (%) | | | | | | |

As shown, stiffness of the sample increased significantly upon curing, based upon the Young's modulus, even though only a cured layer approximately 40 microns thick was obtained on each face of the sample. The uncured sample was also much more visually flexible than was the cured sample. The decreased elongation at break value is indicative of the presence of a rigid crosslinked polymer-PZT particle network within the PCL matrix.

All documents described herein are incorporated by reference herein for purposes of all jurisdictions where such practice is allowed, including any priority documents and/or testing procedures to the extent they are not inconsistent with this text. As is apparent from the foregoing general description and the specific embodiments, while forms of the disclosure have been illustrated and described, various modifications can be made without departing from the spirit and scope of the disclosure. Accordingly, it is not intended that the disclosure be limited thereby. For example, the compositions described herein may be free of any component, or composition not expressly recited or disclosed herein. Any method may lack any step not recited or disclosed herein. Likewise, the term “comprising” is considered synonymous with the term “including.” Whenever a method, composition, element or group of elements is preceded with the transitional phrase “comprising,” it is understood that we also contemplate the same composition or group of elements with transitional phrases “consisting essentially of,” “consisting of,” “selected from the group consisting of,” or “is” preceding the recitation of the composition, element, or elements and vice versa.

Unless otherwise indicated, all numbers expressing quantities of ingredients, properties such as molecular weight, reaction conditions, and so forth used in the present specification and associated claims are to be understood as being modified in all instances by the term “about.” Accordingly, unless indicated to the contrary, the numerical parameters set forth in the following specification and attached claims are approximations that may vary depending upon the desired properties sought to be obtained by the embodiments of the present invention. At the very least, and not as an attempt to limit the application of the doctrine of equivalents to the scope of the claim, each numerical parameter should at least be construed in light of the number of reported significant digits and by applying ordinary rounding techniques.

Whenever a numerical range with a lower limit and an upper limit is disclosed, any number and any included range falling within the range is specifically disclosed. In particular, every range of values (of the form, “from about a to about b,” or, equivalently, “from approximately a to b,” or, equivalently, “from approximately a-b”) disclosed herein is to be understood to set forth every number and range encompassed within the broader range of values. Also, the terms in the claims have their plain, ordinary meaning unless otherwise explicitly and clearly defined by the patentee. Moreover, the indefinite articles “a” or “an,” as used in the claims, are defined herein to mean one or more than one of the element that it introduces.

One or more illustrative embodiments are presented herein. Not all features of a physical implementation are described or shown in this application for the sake of clarity. It is understood that in the development of a physical embodiment of the present disclosure, numerous implementation-specific decisions must be made to achieve the developer's goals, such as compliance with system-related, business-related, government-related and other constraints, which vary by implementation and from time to time. While a developer's efforts might be time-consuming, such efforts would be, nevertheless, a routine undertaking for one of ordinary skill in the art and having benefit of this disclosure.

Therefore, the present disclosure is well adapted to attain the ends and advantages mentioned as well as those that are inherent therein. The particular embodiments disclosed above are illustrative only, as the present disclosure may be modified and practiced in different but equivalent manners apparent to one having ordinary skill in the art and having the benefit of the teachings herein. Furthermore, no limitations are intended to the details of construction or design herein shown, other than as described in the claims below. It is therefore evident that the particular illustrative embodiments disclosed above may be altered, combined, or modified and all such variations are considered within the scope and spirit of the present disclosure. The embodiments illustratively disclosed herein suitably may be practiced in the absence of any element that is not specifically disclosed herein and/or any optional element disclosed herein.

1. A composition comprising:
a polymer material comprising at least one thermoplastic polymer, at least one polymer precursor, or any combination thereof; and
a plurality of piezoelectric particles dispersed in at least a portion of the polymer material;
wherein the piezoelectric particles:
1) interact non-covalently with at least a portion of the polymer material by π-π bonding, hydrogen bonding, electrostatic interactions stronger than van der Waals interactions, or any combination thereof;
2) are covalently bonded to at least a portion of the polymer material;
3) are reactive with at least a portion of the polymer material to form at least one covalent bond thereto under specified conditions; or
4) any combination thereof;
wherein the composition is extrudable and formable into a self-standing three-dimensional structure upon being extruded.

2. The composition of claim 1, wherein the polymer material comprises at least one thermoplastic polymer, and the piezoelectric particles are covalently bonded to the at least one thermoplastic polymer, are reactive with the at least one thermoplastic polymer under the specified conditions, interact non-covalently with the at least one thermoplastic polymer, or any combination thereof.

3. The composition of claim 1, wherein the polymer material comprises at least one polymer precursor, and the piezoelectric particles are reactive with the at least one polymer precursor, or a polymerized form thereof, under the specified conditions to form a covalent bond thereto.

4. (canceled)

5. (canceled)

6. (canceled)

7. (canceled)

8. (canceled)

9. (canceled)

10. (canceled)

11. (canceled)

12. The composition of claim 1, wherein the polymer material and the piezoelectric particles collectively define a composite having a form factor selected from the group consisting of a composite filament, a composite pellet, a composite powder, and a composite paste.

13. The composition of claim 12, wherein the piezoelectric particles are uniformly dispersed in at least a portion of the polymer material.

14. (canceled)

15. The composition of claim 1, wherein the polymer material and the piezoelectric particles collectively define a composite filament.

16. The composition of claim 1, wherein the piezoelectric particles are substantially non-agglomerated when combined with the polymer material.

17. The composition of claim 1, wherein the piezoelectric particles have an average particle size of about 10 microns or less.

18. (canceled)

19. The composition of claim 1, wherein the polymer material comprises at least one thermoplastic polymer.

20. The composition of claim 19, wherein the at least one thermoplastic polymer comprises a first thermoplastic polymer and a second thermoplastic polymer that are immiscible with each other.

21. (canceled)

22. (canceled)

23. (canceled)

24. (canceled)

25. An additive manufacturing process comprising:
providing the composition of claim 1; and
forming a printed part by depositing the composition layer-by-layer.

26. The additive manufacturing process of claim 25, wherein the polymer material comprises at least one thermoplastic polymer, and the composition is heated at or above a melting point or softening temperature of the at least one thermoplastic polymer when forming the printed part.

27. The additive manufacturing process of claim 26, wherein the piezoelectric particles are covalently bonded to the at least one thermoplastic polymer, are reactive with the at least one thermoplastic polymer under the specified conditions, interact non-covalently with the at least one thermoplastic polymer, or any combination thereof.

28. The additive manufacturing process of claim 25, wherein the polymer material comprises at least one polymer precursor comprising a polymerizable monomer or oligomer or a curable resin, the additive manufacturing process further comprising:
exposing the printed part to conditions that polymerize the polymerizable monomer or oligomer or crosslink the curable resin.

29. (canceled)

30. (canceled)

31. (canceled)

32. (canceled)

33. The additive manufacturing process of claim 28, wherein the polymer material further comprises at least one thermoplastic polymer.

34. The additive manufacturing process of claim 25, wherein the polymer material and the piezoelectric particles collectively define a composite having a form factor selected from the group consisting of a composite filament, a composite pellet, a composite powder, and a composite paste.

35. The additive manufacturing process of claim 25, wherein the piezoelectric particles are uniformly dispersed in at least a portion of the polymer material.

36. The additive manufacturing process of claim 25, wherein the piezoelectric particles are substantially non-agglomerated when combined with the polymer material.

37. (canceled)

38. The additive manufacturing process of claim 25, further comprising:
poling at least a portion of the printed part.

39. The additive manufacturing process of claim 25, wherein the polymer material and the piezoelectric particles collectively define a composite filament, and forming the printed part comprises a fused filament fabrication process.

40. (canceled)
